(19) United States
(12) Patent Application Publication
(10) Pub. No.: US 2019/0305157 A1
(43) Pub. Date: Oct. 3, 2019

(54) PHOTODETECTOR

(71) Applicant: The Government of the United States of America, as represented by the Secretary of the Navy, Arlington, VA (US)

(72) Inventors: Francis J. Kub, Arnold, MD (US); Travis J. Anderson, Alexandria, VA (US); Karl D. Hobart, Alexandria, VA (US); Andrew D. Koehler, Alexandria, VA (US)

(21) Appl. No.: 15/943,234

(22) Filed: Apr. 2, 2018

(51) Int. Cl. H01L 31/0352; H01L 31/0224; H01L 31/18; H01L 31/0304

(52) U.S. Cl. CPC H01L 31/03529; H01L 31/03046; H01L 31/18; H01L 31/0224

(57) ABSTRACT

An extreme ultraviolet (EUV) photodetector is formed by providing a substrate having a first doping type of material; forming a photodetector body layer having the first doping type of material over the substrate, wherein the photodetector body layer includes a carrier collection region and a potential barrier maximum level; and forming a carrier collection material layer over the photodetector body layer. The carrier collection region includes a region between the potential barrier maximum level and the carrier collection material layer. The potential barrier maximum level includes a height within the photodetector body layer that prevents photogenerated carriers created at a depth deeper than the potential barrier maximum level from transporting to the carrier collection region and the carrier collection material layer.

### GOVERNMENT INTEREST

The embodiments herein may be manufactured, used, and/or licensed by or for the United States Government without the payment of royalties thereon.

### BACKGROUND

### Technical Field

The embodiments herein generally relate to photodetectors, and more particularly to extreme ultraviolet (EUV) detectors.

### Description of the Related Art

Conventional EUV detectors often have low quantum efficiency, are rather large in size, and may have a limited wavelength range. Conventional detectors may include solid state devices including SiC Schottky diodes, as well as microchannel plate EUV detectors. Solid state devices may suffer from poor quantum efficiency at EUV (10-121 nm) wavelengths due to the light absorption in the metal electrodes. Furthermore, solid state devices typically detect at all energy levels above the bandgap level, which means that these devices are not designed to be solar blind. Microchannel plate EUV detectors are generally large in size (i.e., approximately 1 m), suffer from poor quantum efficiency (i.e., approximately 10-20%), and require high voltage levels for operation.

### SUMMARY

In view of the foregoing, an embodiment herein provides an EUV photodetector comprising a substrate comprising a first doping type of material; a bias semiconductor layer comprising a second doping type of material and positioned over the substrate; a photodetector body layer comprising the first doping type of material and positioned over the bias semiconductor layer, wherein the photodetector body layer comprises a carrier collection region and a potential barrier maximum level; and a carrier collection material layer positioned over the photodetector body layer, wherein the carrier collection region comprises a region between the potential barrier maximum level and the carrier collection material layer, and wherein the potential barrier maximum level comprises a height within the photodetector body layer that prevents photogenerated carriers created at a depth deeper than the potential barrier maximum level from transporting to the carrier collection region and the carrier collection material layer.

The EUV photodetector may further comprise an anode electrode contacting the photodetector body layer; and a cathode electrode contacting the carrier collection material layer. The EUV photodetector may further comprise a first electrode contacting the bias semiconductor layer; and a second electrode contacting the substrate. The bias semiconductor layer may comprise a wide bandgap semiconductor material. The EUV photodetector may further comprise any of a stacked semiconductor layer, a doped semiconductor layer, an insulating layer, and a semi-insulating layer under the photodetector body layer. The substrate may comprise any of a low doping concentration, a semi-insulating, and an insulating substrate. The carrier collection material layer may comprise graphene.

Another embodiment provides an EUV photodetector comprising a substrate comprising a first doping type of material; a photodetector body layer comprising the first doping type of material and positioned over the substrate, wherein the photodetector body layer comprises a carrier collection region and a potential barrier maximum level; and a carrier collection material layer positioned over the photodetector body layer, wherein the carrier collection region comprises a region between the potential barrier maximum level and the carrier collection material layer, and wherein the potential barrier maximum level comprises a height within the photodetector body layer that prevents photogenerated carriers created at a depth deeper than the potential barrier maximum level from transporting to the carrier collection region and the carrier collection material layer. The EUV photodetector may further comprise an anode electrode contacting the photodetector body layer; and a cathode electrode contacting the carrier collection material layer. The EUV photodetector may further comprise a bias semiconductor layer comprising a second doping type of material and positioned over the substrate.

The EUV photodetector may further comprise a first electrode contacting the bias semiconductor layer; and a second electrode contacting the substrate. The bias semiconductor layer may comprise a wide bandgap semiconductor material. The EUV photodetector may further comprise any of a stacked semiconductor layer, a doped semiconductor layer, an insulating layer, and a semi-insulating layer under the photodetector body layer. The substrate may comprise any of a low doping concentration, a semi-insulating, and an insulating substrate. The EUV photodetector may further comprise any of a bandgap layer and an insulator layer between the substrate and photodetector body layer.

Another embodiment provides a method of forming an EUV photodetector, the method comprising providing a substrate comprising a first doping type of material; forming a photodetector body layer comprising the first doping type of material over the substrate, wherein the photodetector body layer comprises a carrier collection region and a potential barrier maximum level; and forming a carrier collection material layer over the photodetector body layer, wherein the carrier collection region comprises a region between the potential barrier maximum level and the carrier collection material layer, and wherein the potential barrier maximum level comprises a height within the photodetector body layer that prevents photogenerated carriers created at a depth deeper than the potential barrier maximum level from transporting to the carrier collection region and the carrier collection material layer.

The method may further comprise forming a bias semiconductor layer comprising a second doping type of material over the substrate. The method may further comprise depleting a doping concentration of any of the substrate, the photodetector body layer, and the bias semiconductor layer. The method may further comprise adjusting the height of the potential barrier maximum level. The method may further comprise configuring the substrate to prevent transporting of photogenerated carriers to the thin carrier collection region.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF THE DRAWINGS

The embodiments herein will be better understood from the following detailed description with reference to the drawings, in which:

FIG. 1 is a cross-sectional view and band diagram of a photodetector device with a thin carrier collection region, according to an embodiment herein;

FIG. 2 is a cross-sectional view and band diagram of a tunable EUV photodetector device, according to an embodiment herein;

FIG. 3 is a cross-sectional view and band diagram of a photodetector device with a thin carrier collection region and low capacitance, according to an embodiment herein;

FIG. 4 is a cross-sectional view and band diagram of a photodetector device with a tunable wavelength responsivity, according to an embodiment herein;

FIG. 5 is a cross-sectional view and band diagram of a photodetector device with a short minority carrier lifetime substrate, according to an embodiment herein;

FIG. 6 is a cross-sectional view and band diagram of a photodetector device with a backside potential barrier, according to an embodiment herein;

FIG. 7 is a cross-sectional view and band diagram of a solar blind tunable EUV photodetector device, according to an embodiment herein;

FIG. 8 is a cross-sectional view and band diagram of a solar blind EUV photodetector device, according to an embodiment herein;

FIG. 9 is a cross-sectional view and band diagram of a tunable EUV photodetector device, according to an embodiment herein;

FIG. 10A is a cross-sectional view of a frontside illuminated/frontside contacted UV/EUV photodetector device, according to an embodiment herein;

FIG. 10B is a cross-sectional view of a frontside illuminated/frontside photodetector device with a regrown epitaxial layer, according to an embodiment herein;

FIG. 10C is a cross-sectional view of a frontside illuminated/frontside photodetector device with an epitaxial layer, according to an embodiment herein;

FIG. 10D is a cross-sectional view of a frontside illuminated/frontside contacted UV/EUV photodetector device, according to an embodiment herein;

FIG. 10E is a cross-sectional view of a frontside illuminated/backside contacted UV/EUV photodetector device, according to an embodiment herein;

FIG. 10F is a cross-sectional view of a frontside illuminated/backside Schottky contact UV/EUV graphene on semiconductor photodetector device, according to an embodiment herein;

FIG. 10G is a cross-sectional view of a frontside illuminated/backside ohmic contact UV/EUV graphene on semiconductor photodetector device, according to an embodiment herein;

FIG. 10H is a cross-sectional view of a frontside illuminated/backside Schottky contact UV/EUV graphene on semiconductor photodetector device, according to an embodiment herein;

FIG. 11A is cross-sectional view illustrating a first step in manufacturing a first photodetector device, according to an embodiment herein;

FIG. 11B is cross-sectional view illustrating a second step in manufacturing a second photodetector device, according to an embodiment herein;

FIG. 11C is cross-sectional view illustrating a third step in manufacturing a second photodetector device, according to an embodiment herein;

FIG. 11D is cross-sectional view illustrating a fourth step in manufacturing a second photodetector device, according to an embodiment herein;

FIG. 11E is cross-sectional view illustrating a fifth step in manufacturing a second photodetector device, according to an embodiment herein;

FIG. 11F is cross-sectional view illustrating a sixth step in manufacturing a second photodetector device, according to an embodiment herein;

FIG. 12A is cross-sectional view illustrating a first step in manufacturing a second photodetector device, according to an embodiment herein;

FIG. 12B is cross-sectional view illustrating a second step in manufacturing a second photodetector device, according to an embodiment herein;

FIG. 12C is cross-sectional view illustrating a third step in manufacturing a second photodetector device, according to an embodiment herein;

FIG. 12D is cross-sectional view illustrating a fourth step in manufacturing a second photodetector device, according to an embodiment herein;

FIG. 12E is cross-sectional view illustrating a fifth step in manufacturing a second photodetector device, according to an embodiment herein;

FIG. 12F is cross-sectional view illustrating a sixth step in manufacturing a second photodetector device, according to an embodiment herein;

FIG. 13A is cross-sectional view illustrating a first step in manufacturing a third photodetector device, according to an embodiment herein;

FIG. 13B is cross-sectional view illustrating a second step in manufacturing a third photodetector device, according to an embodiment herein;

FIG. 13C is cross-sectional view illustrating a third step in manufacturing a third photodetector device, according to an embodiment herein;

FIG. 13D is cross-sectional view illustrating a fourth step in manufacturing a third photodetector device, according to an embodiment herein;

FIG. 13E is cross-sectional view illustrating a fifth step in manufacturing a third photodetector device, according to an embodiment herein;

FIG. 13F is cross-sectional view illustrating a sixth step in manufacturing a third photodetector device, according to an embodiment herein;

FIG. 14A is cross-sectional view illustrating a first step in manufacturing a fourth photodetector device, according to an embodiment herein;

FIG. 14B is cross-sectional view illustrating a second step in manufacturing a fourth photodetector device, according to an embodiment herein;

FIG. 14C is cross-sectional view illustrating a third step in manufacturing a fourth photodetector device, according to an embodiment herein;

FIG. 14D is cross-sectional view illustrating a fourth step in manufacturing a fourth photodetector device, according to an embodiment herein;

FIG. 14E is cross-sectional view illustrating a fifth step in manufacturing a fourth photodetector device, according to an embodiment herein;

FIG. 14F is cross-sectional view illustrating a sixth step in manufacturing a fourth photodetector device, according to an embodiment herein;

FIG. 15A is cross-sectional view illustrating a first step in manufacturing a fifth photodetector device, according to an embodiment herein;

FIG. 15B is cross-sectional view illustrating a second step in manufacturing a fifth photodetector device, according to an embodiment herein;

FIG. 15C is cross-sectional view illustrating a third step in manufacturing a fifth photodetector device, according to an embodiment herein;

FIG. 15D is cross-sectional view illustrating a fourth step in manufacturing a fifth photodetector device, according to an embodiment herein;

FIG. 15E is cross-sectional view illustrating a fifth step in manufacturing a fifth photodetector device, according to an embodiment herein;

FIG. 15F is cross-sectional view illustrating a sixth step in manufacturing a fifth photodetector device, according to an embodiment herein; and

FIG. 16 is a flow diagram illustrating a method, according to an embodiment herein.

### DETAILED DESCRIPTION

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

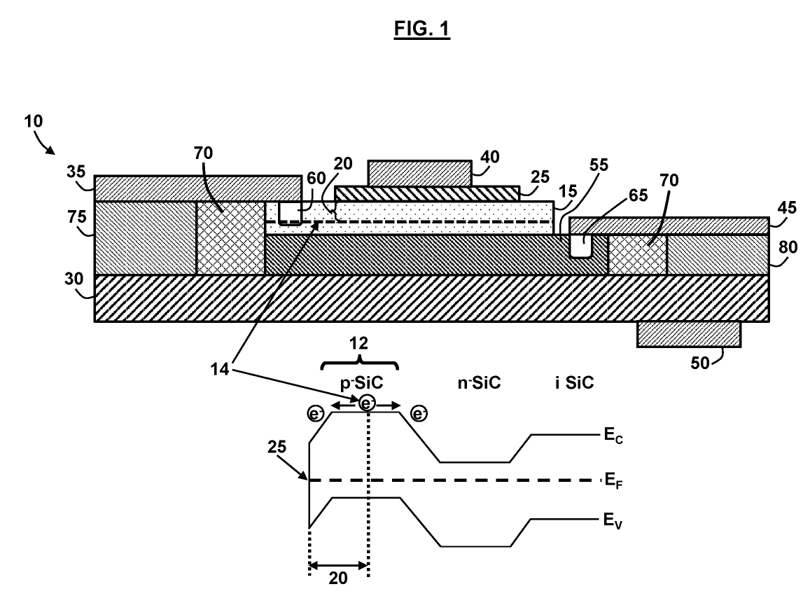

An embodiment herein provide a EUV solar-blind photodetector with a low photodetector capacitance. Referring now to the drawings, and more particularly to FIGS. 1 through 16, where similar reference characters denote corresponding features consistently throughout the figures, there are shown exemplary embodiments.

Example photodetector devices are described in accordance with the embodiments herein. According to a first example, a photodetector device may provide one or more of the features of a thin carrier collection region that permits the photodetector to have low responsibility for light with a wavelength generated by the sun. According to second example, a photodetector device may provide a thin carrier collection region and low photodetector capacitance (e.g., low capacitance between the cathode electrode connected to the carrier collection material layer and anode electrode of the photodetector and low capacitance between the carrier collection anode electrode and the substrate). According to a third example, a photodetector device may provide a tunable wavelength responsivity by modifying the thickness (e.g., height or depth) of the carrier collection region by adjusting the electrical bias on the carrier collection anode material layer and the bias semiconductor layer relative to the bias on the photodetector body layer. According to a fourth example, a photodetector device may provide a low photodetector cathode capacitance and optionally a thin carrier collection region using a limited diffusion length in a short minority carrier substrate. According to a fifth example, a photodetector device may provide a low photodetector cathode capacitance and optionally a thin carrier collection region using a backside potential barrier region.

The thin carrier collection region photodetector may be used to implement the following classes of UV/EUV photodetectors, for example: PiN photodetector, Schottky metal carrier collection material layer photodetector, graphene carrier collection material layer photodetector, non-avalanched photodetector, avalanched photodetector, and Geiger mode photodetector.

The various example photodetector devices indicated above are described in greater detail below:

Photodetector Device with Thin Carrier Collection Region

FIG. 1 illustrates a photodetector device 10a that may provide one or more of the features of a thin carrier collection region that permits the photodetector device 10a to have low responsibility for light with a wavelength generated by the sun. The photodetector device 10a has an internal potential barrier 12 with a potential barrier maximum 14 within a photodetector body layer 15 that prevents photogenerated carriers created at a height or depth deeper than the potential barrier maximum 14 from transporting to the carrier collection region 20 and then be further transported to the carrier collection material layer 25. Photodetectors with low responsivity to light generated by the sun may have the feature of being solar blind. The photodetector device 10a may be fabricated using wide bandgap semiconductor materials. The thin carrier collection region 20 photodetector may be a solar blind photodetector. The thin carrier collection region 20 may be an ultraviolet photodetector, an extreme ultraviolet photodetector, a vacuum UV photodetector, a solar blind ultraviolet photodetector, a solar blind extreme ultraviolet photodetector, or a solar blind vacuum UV photodetector, according to various examples. The thin carrier collection region 20 may enable low leakage current that is collected by the carrier collection material layer 25. The thin carrier collection region 20 may enable high temperature operation while maintaining low leakage current by the carrier collection material layer 25.

The photodetector device 10 comprises a substrate 30 of one doping type property (for example, P-type semiconductor property) or a semi-insulting property or an insulator property or a metal property, a bias semiconductor layer 55 of a second doping type (for example, N-type semiconductor property), a photodetector body layer 15 of a first doping type (for example, P-type semiconductor property), and a carrier collection material layer 25. The photodetector device 10 may also comprise an anode electrode 35 in contact with the photodetector body layer 15, a cathode electrode 40 in contact with the carrier collection material layer 25, an optional bias electrode 45 in contact with the bias semiconductor layer 55, and an optional electrode 50 in contact with the substrate 30. A contact pad 75 is positioned between the anode electrode 35 and the substrate 30, and a contact pad 80 is positioned between the bias electrode 45 and the substrate 30. The photodetector body layer 15 may have a laterally defined heavily doped region 60 (for example, P+) to facilitate the anode electrode 35 making an ohmic contact to the photodetector body layer 15. The carrier collection material layer 25 may have a heavily doped region 60 (for example P+) to facilitate the cathode electrode 40 making an ohmic contact to the carrier collection material layer 25. The bias semiconductor layer 55 may have a laterally defined heavily doped region 65 (for example N+) to facilitate the bias electrode 45 making an ohmic contact to the bias semiconductor layer 55. The photodetector device 10 may further comprise oxide regions 70 adjacent to the bias semiconductor layer 55.

The photodetector device 10 comprises an internal potential barrier 12 with a potential barrier maximum 14 within the photodetector body layer 15 that prevents photogenerated carriers created at a depth deeper than the potential barrier maximum 14 from transporting to the carrier collection region 20 and then be further transported to the carrier collection material layer 25. In one example, the bias semiconductor layer 55 may have the opposite doping type as the doping type in the photodetector body layer 15. The bias semiconductor layer 55 is located beneath the photodetector body layer 15. In alternate embodiments, there may be additional stacked semiconductor, doped semiconductor layers, semiconductor insulating layers, or semiconductor semi-insulating layers beneath the photodetector body layer 15 that form a potential barrier 12 that provides the feature of a thin carrier collection region 20. The photodetector device with the thin carrier collection region 20 enables the photodetector to have low responsibility for light with a wavelength generated by the sun. Photodetectors with low responsivity to light generated by the sun may be solar blind. The thin carrier collection region 20 photodetector may be a solar blind photodetector. The thin carrier collection region 20 may be an ultraviolet photodetector, an extreme ultraviolet photodetector, a vacuum UV photodetector, a solar blind ultraviolet photodetector, a solar blind extreme ultraviolet photodetector, or a solar blind vacuum UV photodetector. The photodetector device 10 may be fabricated using wide bandgap semiconductor materials that may include, but are not limited to, silicon carbide, gallium nitride, aluminum gallium nitride, gallium oxide, and boron nitride. The wide bandgap semiconductor may be an indirect bandgap material or may be a direct band gap material. An indirect bandgap material will typically have a larger 1/e absorption length (depth) than a direct bandgap material. The large 1/e absorption length may help implement the solar blind function since a significant fraction of the solar wavelength photogenerated carriers will be created at a depth then the potential barrier maximum 14.

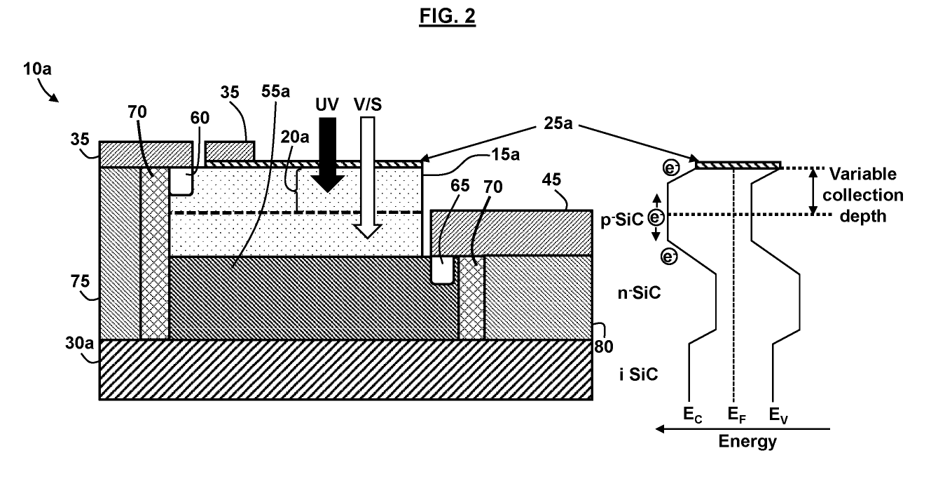

In some embodiments, the solar-blind feature of the detector occurs by implementing a thin carrier collection region photodetector 10a on wide bandgap material, as shown in FIG. 2, with reference to FIG. 1. Silicon carbide has a bandgap of 3.26 eV. Thus, ultraviolet detectors fabricated on silicon carbide will have low responsivity for wavelengths longer than 360 nm. Additional components of the solar spectrum may be removed by implementing a thin carrier collection region 20 in the photodetector 10a. Only those solar wavelengths absorbed within a 100 nm of the surface will be collected within the photodetector 10a shown in FIG. 2. The 1/e absorption depth for photons with a 360 nm wavelength is 49 microns. Thus, additional components of the solar spectrum are rejected by implementing the thin carrier collection region 20. The ultrathin, solar blind or nearly solar blind EUV detector may reduce optical filtering requirements to remove the solar spectrum.

In one example, the bias semiconductor layer 55a may have the opposite doping type as the doping type in the photodetector body layer 15a. The bias semiconductor layer 55a is located beneath the photodetector body layer 15a. Silicon carbide may be utilized to form a photodetector with a thin carrier collection region 20a since a graphene material layer 25a may be grown on the silicon carbide surface (e.g., on the photodetector body layer 15a) by heating to desorb silicon atoms from the surface of the photodetector body layer 15a. The graphene carrier collection material layer 25a may assist in enhancing the effects of EUV and vacuum UV photodetectors since the carrier collection material layer 25a is very thin and will not absorb a significant fraction of EUV or vacuum UV photons.

Photodetector Device with Thin Collection Region and Low Photodetector Capacitance

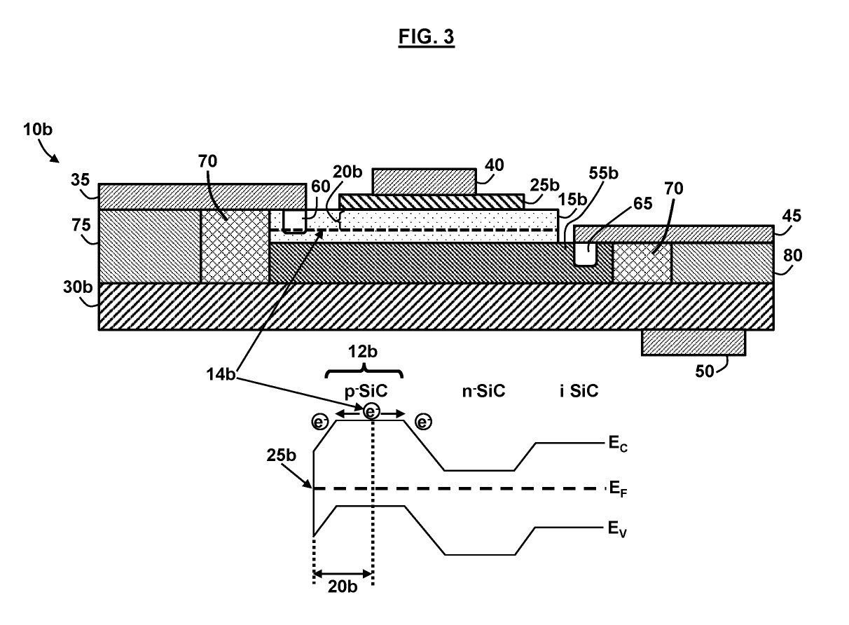

FIG. 3, with reference to FIGS. 1 and 2, illustrates a second photodetector device 10b, which may provide the feature of thin carrier collection region 20b and low photodetector capacitance (e.g., low capacitance between the cathode electrode 40 connected to the carrier collection material layer 25b and anode electrode 35 of the photodetector device 10b and low capacitance between the carrier collection anode electrode 35 and the substrate 30). The photodetector device 10b comprises an internal potential barrier 12b with a potential barrier 12b maximum within the photodetector body layer 15b that prevents photogenerated carriers created at a depth deeper than the potential barrier maximum 14b from transporting to the carrier collection region 20b and then be further transported to the carrier collection material layer 25b. One or more of the semiconductor layers (e.g., layers 15b, 30b, 55b) in the photodetector 10b may be depleted to enable reduction in the photodetector capacitance. Accordingly, the photodetector body layer 15b may be depleted, and the bias semiconductor layer 55b may be depleted. Moreover, a portion of the substrate 30b or the entire substrate 30b may be depleted. The photodetector device 10b may be fabricated on a high resistivity or semi-insulating substrate 30b to provide further reduction in photodetector capacitance.

In some embodiments, the photodetector device 10b may be designed for low photodetector capacitance. The low capacitance is achieved by selecting the doping concentration in the bias semiconductor layer 55b to be depleted and the photodetector body layer 15b to be depleted. A bias voltage may be applied between the cathode electrode 40 and the anode electrode 35 to aid in depleting the bias semiconductor layer 55b and the photodetector body layer 15b. The built-in field at the interface of the carrier collection material layer 25b and the photodetector body layer 15b may also be selected to facilitate depleting the photodetector body layer 15b. In some embodiments, the doping in the bias semiconductor layer 55b and the photodetector body layer 15b may be selected so that the bias semiconductor layer 55b and the photodetector body layer 15b are depleted with zero bias applied between the anode electrode 35 and the cathode electrode 40. Additional reduction in capacitance may be obtained if a low doping concentration, a semi-insulating, or an insulating substrate 30b is used since the depletion layer beneath the carrier collection material layer 25b will extend some distance into the substrate 30b. For an embodiment in which a semi-insulating silicon carbide (SiC) substrate 30b is used, the depletion layer will extend a significant distance into the semi-insulating SiC substrate 30b and thus, the detector capacitance will be extremely low.

The capacitance of the detector bond pads is minimized by forming on the semi-insulating SiC substrate 30b. The input referred noise of the readout amplifier is a strong function of the detector capacitance and thus the input referred noise will be minimized. Because of the potential profile of the n-SiC epitaxial layer, leakage current from the substrate 30 will be collected into the n-SiC epitaxial layer and thus will not be collected by the readout electrode.

The photodetector device 10b has an internal potential barrier 12b with a potential barrier maximum 14b within the photodetector body layer 15 that prevents photogenerated carriers created at a depth deeper than the potential barrier 12b maximum from transporting to the carrier collection region 20b and then be further transported to the carrier collection material layer 25b. The potential barrier 12b maximum establishes a thin carrier collection region 20b. Thus, the photodetector device 10b has both thin carrier collection region 20b and low photodetector capacitance.

Photodetector Device with Tunable Wavelength Responsivity

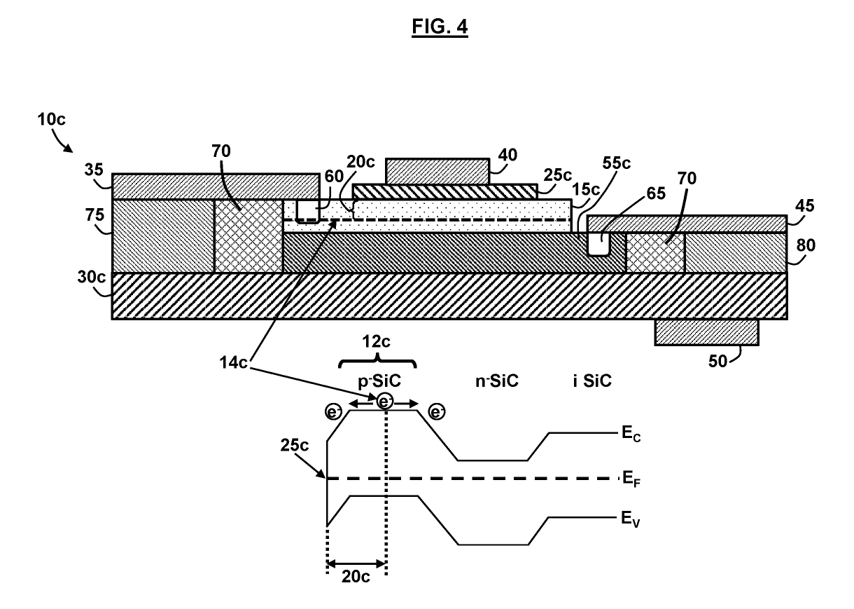

FIG. 4, with reference to FIGS. 1 through 3, illustrates a third photodetector device 10c, which may provide the feature of tunable wavelength responsivity by modifying the thickness (depth) of the carrier collection region 20c by adjusting the electrical bias on the carrier collection material layer 25c and the bias semiconductor layer 55c relative to the bias on the photodetector body layer 15c. The photodetector device 10c comprises an internal potential barrier 12c with a potential barrier maximum 14c within the photodetector body layer 15c that prevents photogenerated carriers created at a depth deeper than the potential barrier maximum 14c from transporting to the carrier collection region 20c and then be further transported to the carrier collection material layer 25c.

In an embodiment, the photodetector device 10c may provide the features of a thin carrier collection region 20c and tunable thickness of the thin carrier collection region 20c to allow a tunable wavelength responsivity. The photodetector device 10c may have a substrate 30c of one doping type property (for example, P-type semiconductor property) or a semi-insulting property or an insulator property or a metal property, a bias semiconductor layer 55c of a second doping type (for example N-type), a photodetector body layer 15c of a first doping type (for example P-type), and a carrier collection material layer 25c. The photodetector device 10c also comprises an anode electrode 35 in contact with the photodetector body layer 15c, a cathode electrode 40 in contact with the carrier collection material layer 25c, an optional bias electrode 45 in contact with the bias semiconductor layer 55c, and an optional electrode 50c in contact with the substrate 30c. The photodetector body layer 15c may have a laterally defined heavily doped region 60 (for example P+) to facilitate the anode electrode 35 making an ohmic contact with the photodetector body layer 15c. The carrier collection material layer 25c may have a heavily doped region (for example P+) to facilitate the cathode electrode 40 making an ohmic contact with the carrier collection material layer 25c. The bias semiconductor layer 55c may have a laterally defined heavily doped region 65 (for example N+) to facilitate the bias electrode 45 making an ohmic contact with the bias semiconductor layer 55c.

The photodetector device 10c has an internal potential barrier 12c with a potential barrier maximum 14c within the photodetector body layer 15c that prevents photogenerated carriers created at a depth deeper than the potential barrier maximum 14c from transporting to the carrier collection region 20c and then be further transported to the carrier collection material layer 25c. The bias semiconductor layer 55c may have an opposite doping type as the doping type in the photodetector body layer 15c. The bias semiconductor layer 55c is located beneath the photodetector body layer 15c. In alternate embodiments, there may be additional stacked semiconductor, doped semiconductor layers, semiconductor insulating layers, or semiconductor semi-insulating layers beneath the photodetector body layer 15c that form a potential barrier 12c that provides the feature of a thin carrier collection region 20c.

The photodetector device 10c with thin carrier collection region 20c may enable the photodetector device 10c to have low responsibility for light with a wavelength generated by the sun. Photodetectors with low responsivity to light generated by the sun may have the feature of being solar blind. The thin carrier collection region photodetector device 10c may be a solar blind photodetector, in one example. In other examples, the thin carrier collection region photodetector device 10c may be an ultraviolet photodetector, an extreme ultraviolet photodetector, a vacuum UV photodetector, a solar blind ultraviolet photodetector, a solar blind extreme ultraviolet photodetector, or a solar blind vacuum UV photodetector.

The thickness of the thin carrier collection region 20c may be varied (tuned or adjusted) by varying the bias voltage on the anode electrode 35 and the bias electrode 45. A higher bias will cause the potential barrier maximum 14c to change in depth (move farther from the carrier collection material layer 25c) and thus allow a variation in the thickness of the thin carrier collection region 20c which may cause a change in the wavelength responsivity of the photodetector device 10c. A reduced bias voltage difference will cause the potential barrier maximum 14c to change in depth (move closer to the carrier collection material layer 25c).

Photodetector Device with Thin Collection Region and Low Photodetector Capacitance Using Limited Diffusion Length in Short Minority Carrier Substrate

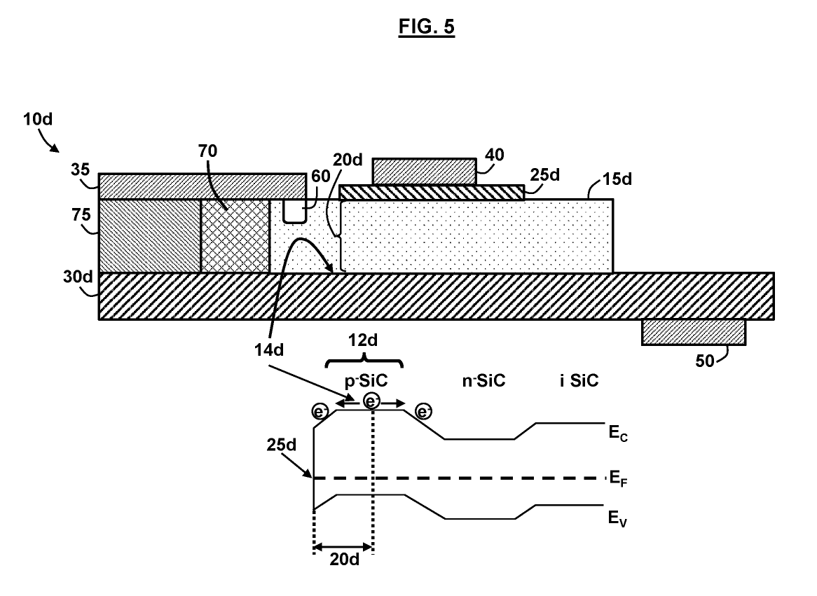

FIG. 5, with reference to FIGS. 1 through 4, illustrates a fourth photodetector device 10d, which may provide the feature of low photodetector cathode capacitance and optionally thin carrier collection region 20d using limited diffusion length in short minority carrier substrate 30d. The photodetector device 10d may use a short photogenerated carrier lifetime in a substrate 30d to make the substrate 30d ineffective for transporting carriers to the thin carrier collection region 20d. A semi-insulating silicon carbide substrate 30d has a short minority carrier lifetime and carriers that are photogenerated in the semi-insulating silicon carbide will recombine and not contribute to the photodetector photocurrent. One or more of the semiconductor layers (e.g., layers 30d, 15d) in the photodetector device 10d may be depleted to enable reduction in the photodetector capacitance. The photodetector body layer 15d may be depleted. A portion of the substrate 30d or the entire substrate 30d may be depleted. The photodetector device 10d may be fabricated on a high resistivity or semi-insulating substrate 30d to provide further reduction in photodetector capacitance. The photogenerated holes may transport laterally to the anode electrode 35.

In some embodiments, the photodetector device 10d may be configured for thin carrier collection region 20d and low photodetector capacitance. The photodetector device 10d may use a short photogenerated carrier lifetime in the substrate 30d to make the substrate 30d ineffective for transporting carriers to the thin carrier collection region 20d. A semi-insulating silicon carbide substrate 30d has a short minority carrier lifetime and carriers that are photogenerated in the semi-insulating silicon carbide will recombine and not contribute to the photodetector photocurrent. The low capacitance is achieved by selecting the doping concentration in the photodetector body layer 15d to be depleted. A bias voltage may be applied between the cathode electrode 40 and anode electrode 35 to aid in depleting the photodetector body layer 15d. The built-in field at the interface of the carrier collection material layer 25d and the photodetector body layer 15d may also be selected to facilitate depleting the photodetector body layer 15d.

In some embodiments, the doping in the photodetector body layer 15d may be selected so that the photodetector body layer 15d are depleted with zero bias applied between the anode electrode 35 and cathode electrode 40. Additional reduction in capacitance is obtained if a low doping concentration, a semi-insulating, or an insulating substrate 30d is used since the depletion layer beneath the carrier collection material layer 25d will extend some distance into the substrate 30d.

For an embodiment in which a semi-insulating SiC substrate 30d is used, the depletion layer will extend a significant distance into the semi-insulating SiC substrate 30d and thus, the detector capacitance will be extremely low. The capacitance of the detector bond pads is minimized by forming on the semi-insulating SiC substrate 30d. The input referred noise of the readout amplifier is a strong function of the detector capacitance and thus the input referred noise will be minimized. Because of the potential profile of the n-SiC epitaxial layer, leakage current from the substrate 30d will be collected into the n-SiC epitaxial layer and thus will not be collected by the readout electrode.

The photodetector device 10d may have an internal potential barrier 12d at the interface between the semi-insulating substrate 30d and the photodetector body layer 15d that prevents photogenerated carriers created at a depth deeper than the internal potential barrier 12d from transporting to the carrier collection region 20d and then be further transported to the carrier collection material layer 25d. The potential barrier maximum 14d establishes a thin carrier collection region 20d. Thus, the photodetector device 10d has both thin carrier collection region 20d and low photodetector capacitance.

Photodetector Device with Thin Collection Region and Low Photodetector Capacitance Using Backside Potential Barrier Material Layer

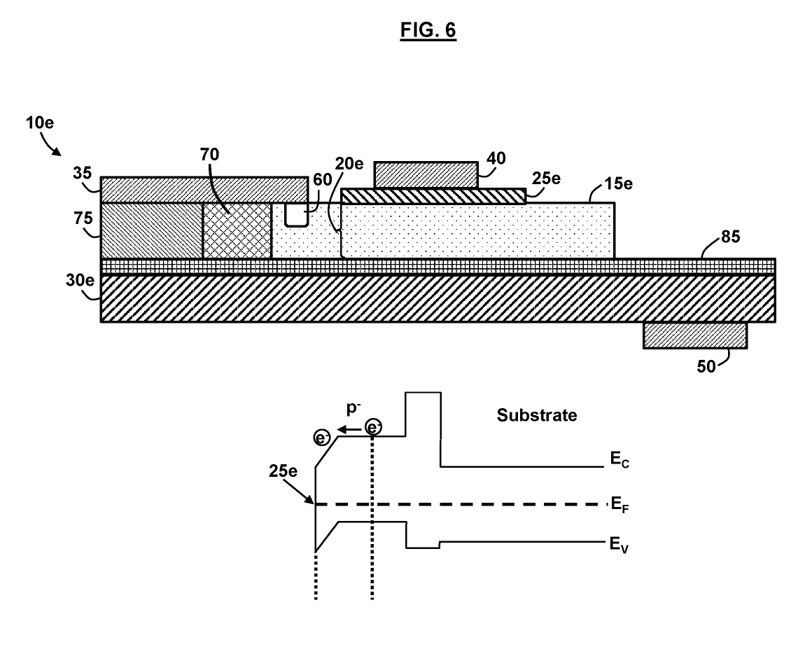

FIG. 6, with reference to FIGS. 1 through 5, illustrates a fifth photodetector device 10e, which may provide the feature of low photodetector cathode capacitance and optionally thin carrier collection region 20e using backside potential barrier region 85. The backside potential barrier region 85 may be a higher bandgap heterojunction material layer or may be an insulating material layer. Photocarriers that are created in the substrate 30e will not be able to transport through the backside potential barrier 85 and thus not be able to be collected in the thin carrier collection region 20e. The photodetector device 10e may have an internal potential barrier 85 that prevents photogenerated carriers created at a depth deeper than the internal potential barrier 85 from transporting to the carrier collection region 20e and then be further transported to the carrier collection material layer 25e.

One or more of the semiconductor layers (e.g., layers 15e, 30e) in the photodetector device 10e may be depleted to enable reduction in the photodetector capacitance. Accordingly, the photodetector body layer 15e may be depleted. Moreover, a portion of the substrate 30e or the entire substrate 30e may be depleted. The photodetector device 10e may be fabricated on a high resistivity or semi-insulating substrate 30e to provide further reduction in photodetector capacitance. The photogenerated holes may transport laterally to the anode electrode 35.

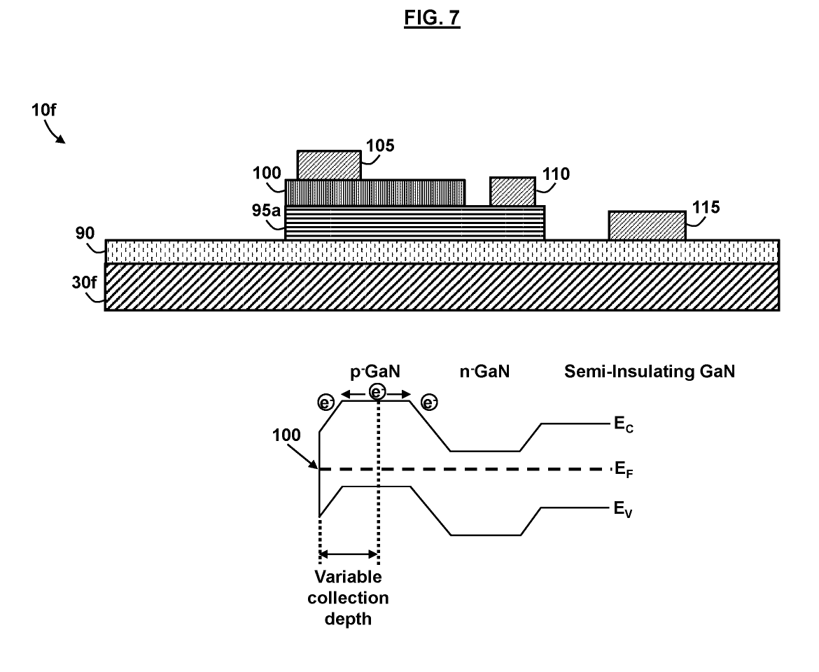

FIG. 7, with reference to FIGS. 1 through 6, illustrates a solar blind tunable EUV photodetector device 10f comprising a substrate 30f comprising a N-type or semi-insulating GaN material, for example, a first semiconductor layer 90 comprising a N-type or GaN material, for example, over the substrate 30f, a second semiconductor layer 95 comprising a p-type or GaN epitaxial layer material, for example, over the first semiconductor layer 90, and a third semiconductor layer 100 comprising a N+ InN epitaxial layer material, for example, over the second semiconductor layer 95a. A first ohmic metal contact 105 is positioned on the third semiconductor layer 100, a second ohmic metal contact 110 is positioned on the second semiconductor layer 95a, and a third ohmic metal contact 115 is positioned on the first semiconductor layer 90.

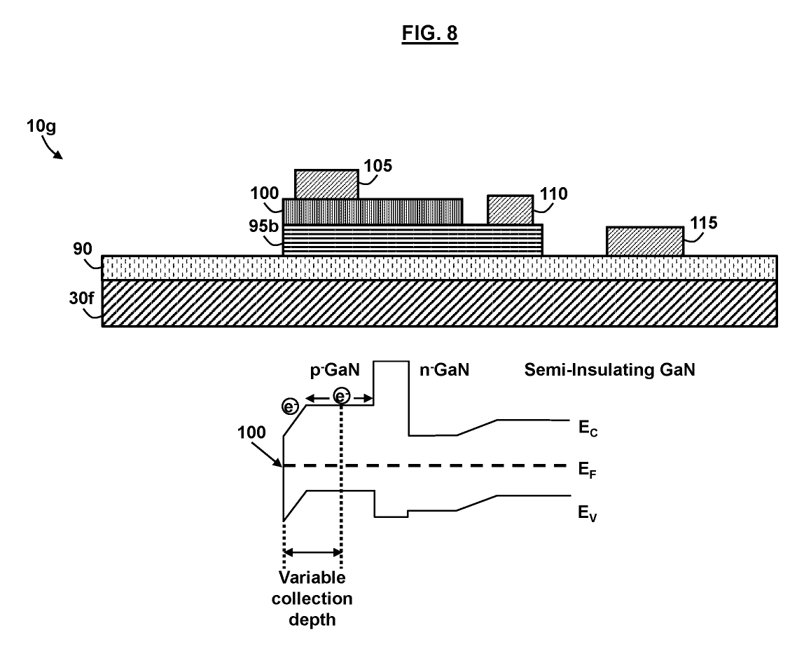

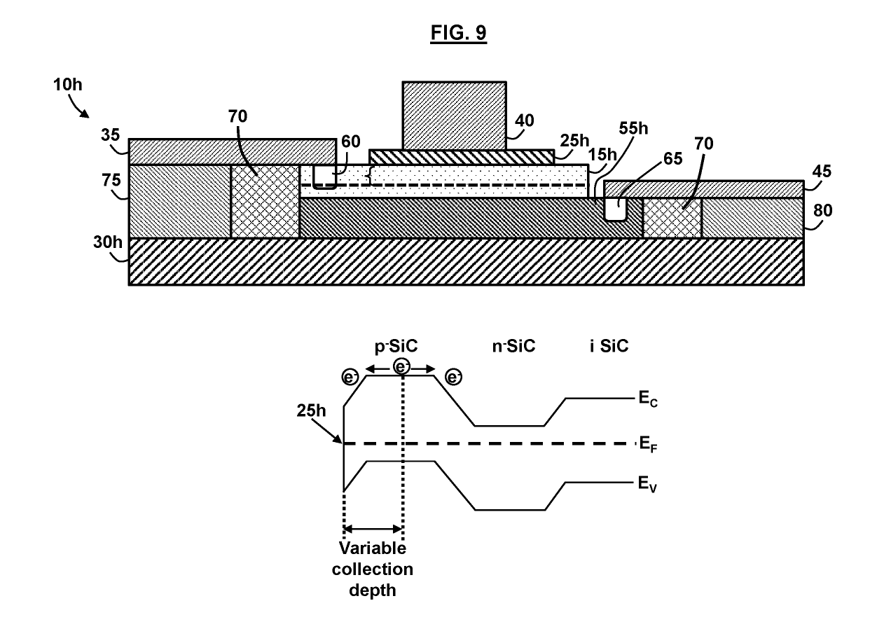

FIG. 8, with reference to FIGS. 1 through 7, illustrates a solar blind EUV photodetector device 10g according to an embodiment herein. The photodetector device 10g is similarly configured to the photodetector device 10f of FIG. 7 except that the first semiconductor layer 95b may comprise AlGaN or AlN barrier material. FIG. 9, with reference to FIGS. 1 through 8, illustrates a tunable EUV photodetector device 10h according to an embodiment herein. The photodetector device 10h comprises a substrate 30h comprising a semi-insulating SiC material, for example, a bias semiconductor layer 55h of a second doping type (for example, N-type SiC epitaxial layer), a photodetector body layer 15h of a first doping type (for example, P-type SiC epitaxial layer), and a carrier collection material layer 25h comprising graphene, for example. The photodetector device 10h may also comprise an anode electrode 35 in contact with the photodetector body layer 15h, a cathode electrode 40 in contact with the carrier collection material layer 25h, an optional bias electrode 45 in contact with the bias semiconductor layer 55h. The electrodes 35, 40, 45 may comprise Ti or Al, for example. A contact pad 75 is positioned between the anode electrode 35 and the substrate 30h, and a contact pad 80 is positioned between the bias electrode 45 and the substrate 30h. The contact pads 75, 80 may help in reducing capacitance in the photodetector device 10h. The photodetector body layer 15h may have a laterally defined heavily doped region 60 (for example, P+) to facilitate the anode electrode 35 making an ohmic contact to the photodetector body layer 15h. The carrier collection material layer 25h may have a heavily doped region 60 (for example P+) to facilitate the cathode electrode 40 making an ohmic contact to the carrier collection material layer 25h. The bias semiconductor layer 55h may have a laterally defined heavily doped region 65 (for example N+) to facilitate the bias electrode 45 making an ohmic contact to the bias semiconductor layer 55h. The photodetector device 10h may further comprise oxide regions 70 adjacent to the bias semiconductor layer 55h. In other examples, the thickness of the photodetector body layer 15h may be reduced in order to reduce the long-wavelength response in the photodetector device 10h. Moreover, the long-wavelength response may be adjusted by adding bias to the photodetector device 10h to select the e⁻ carrier closer to the surface, thereby adjusting the bias toward shorter wavelengths. Furthermore, the photodetector capacitance may be reduced by balancing the N-type and P-type doping concentration so that the n-SiC in the bias semiconductor layer 55h is depleted. The n-Sic in the bias semiconductor layer 55h helps reduce detector leakage current by being a sink for electrons generated in the semi-insulating substrate 30h.

In the subsequent descriptions below reference is made to the various layers and components described with respect to FIG. 1 such as the carrier collection region 20, carrier collection material layer 25, substrate 30, and photodetector body layer 55, for example. However, the descriptions below are applicable to the corresponding structures of FIGS. 2 through 9, and the embodiments herein are not restricted to any one particular configuration or arrangement of structures or layers provided by the above-described examples.

Carrier Collection Anode Electrode

The carrier collection anode electrode 35 for the photodetector with thin carrier collection region 25 may include, but is not limited to, a two-dimensional material layer, graphene layer, molybdenum disulfide layer, molybdenum diselenide layer, Schottky metal layer, semiconductor layer with opposite doping type as the thin carrier collection doping type, N-type indium nitride on P-type III-nitride layer, 2DEG carrier collection layer, p-type doped semiconductor layer, n-type doped semiconductor layer. The carrier collection anode electrode 35 establishes a potential on the surface of the semiconductor material and to collect photogenerated carriers. The semiconductor material may be wide bandgap material with a bandgap greater than 2.0 eV that may include but not be limited to silicon carbide, gallium nitride, aluminum gallium nitride, indium aluminum nitride, zinc oxide, gallium oxide, and diamond. The semiconductor material may be an indirect energy gap semiconductor or a direct energy gap semiconductor.

Substrate

The substrate 30 may be semi-insulating, insulating, or semiconducting. The thin carrier collection region photodetector 10 may be used to implement the following classes of UV/EUV photodetectors, as examples: (a) PiN photodetector, (b) Schottky metal carrier collection material layer photodetector, (c) Graphene carrier collection material layer photodetector, (d) Non-avalanched photodetector, (e) Avalanched photodetector, and (f) Geiger mode photodetector.

Formation of Graphene

There are various approaches to form a graphene material layer on a surface, such as used for the carrier collection material layer 25, which may include (1) Peel-off/transfer method, which is a method in which a layer is peeled off from a graphite crystal using tape, and transferred to the substrate; (2) Chemical Vapor Deposition/transfer (CVD/transfer) method, which is a method in which graphene is formed on a film of metallic catalyst at temperatures of approximately 450-1000° C., and then transferred to a different substrate; (3) SiC surface decomposition method, which is a method in which a semiconductor substrate comprising SiC is heat-treated at approximately 1200-2000° C.

The graphene material layer may be formed on the semiconductor material by epitaxial growth of one or more sheets of graphene on the surface of the semiconductor material layer. One of the techniques for forming graphene on a semiconductor is to epitaxially grow graphene on a SiC surface by growing a sufficiently high temperature to desorb silicon atoms from the silicon carbide surface. It is typically the case that graphene grown on the silicon face of SiC forms a single sheet of graphene on the surface of the SiC. The graphene material layer may also be formed by the transfer of and bonding of graphene material comprising of one or more sheets of graphene to the surface of the semiconductor material. In the transfer and bond approach, graphene sheets are first grown on a substrate 30 such as SiC, copper, nickel or other substrates known by those skilled in the art using CVD, sublimation of silicon as is the case for SiC, or solution growth and by other techniques as known by those skilled in the art. In one example of the transfer and bond approach, a heat releasable tape is adhered to the top surface of the graphene sheet material that is formed on a substrate, the heat releasable tape is lifted from the surface of the substrate with graphene material attached to the bottom surface of the heat releasable tape.

The surface of the semiconductor material to receive the graphene material is suitably prepared for direct bonding of the graphene material layer. The process of suitably preparing the surface of the semiconductor material may include appropriate cleaning and in some cases by appropriate treatment for improving the bond strength of the graphene material or to the surface of the semiconductor material. The surface of the graphene material is then brought into direct contact to the surface of the semiconductor material and the bonding forces present between the surface of the graphene material and the semiconductor material such as van der Waals bonding forces will bond the graphene sheet to the material of the carrier collector region 20. The bond strength of the graphene material to the semiconductor material may be improved by appropriate charging of the surface of the carrier collector region 20 and/or graphene layers/sheets 25 by exposing the surface to plasma or corona. The bond strength of the graphene material to the semiconductor surface of the photodetector body layer 15 may also in some cases be improved by forming hydroxyl ions HO— on the surface of the semiconductor material in the photodetector body layer 15.

In an example, the electrons (holes) are able to transport across the interface between the graphene material (e.g., carrier collection material layer 25) and the semiconductor material (e.g., photodetector body layer 15). Accordingly, if insulating material such as a native oxide or deposited insulator or grown insulator exist on the surface of the semiconductor material (e.g., photodetector body layer 15), then the insulating material should be sufficiently thin such that electrons (holes) may transmit from the semiconductor material (e.g., photodetector body layer 15) into the graphene material (e.g., carrier collection material layer 25). In this case, the surface of the collector semiconductor material is prepared in a suitable manner to minimize the native oxide on the surface. The surface of the semiconductor material (e.g., photodetector body layer 15) may also be prepared to minimize the number of surface states and band bending on the surface of the semiconductor material (e.g., photodetector body layer 15).

For example, forming fluorine atoms on the surface of GaN will remove the band bending at the surface of GaN. There are other approaches for reducing surface states and band bending on the surface of the semiconductor material (e.g., photodetector body layer 15) and thus at the interface of the graphene material/semiconductor region material (e.g., carrier collection region 20).

An example material system for the transfer and bond approach is the graphene on AlGaN or GaN material system. The AlGaN or GaN surface should be prepared prior to the bonding to remove the native oxide that is on the surface. For the case that a P-type graphene layer is desired, there are several methods of forming P-type graphene. There are multiple growth techniques of forming P-type graphene material layers. Graphene sheets that are grown on the carbon face of SiC are often P-type. Graphene sheets intercalated with gold is P-type. Graphene grown by CVD on a copper film are also doped P-type. Graphene sheets grown on the carbon face of SiC are often P-type. N-type graphene may be formed by annealing in ammonia ambient or in a nitrogen ambient. Graphene grown on the silicon face of SiC are often N-type.

The photodetector device 10 for UV and EUV wavelengths has a graphene material layer (e.g., carrier collection material layer 25) on the surface of a semiconductor layer (e.g., photodetector body layer 15) (with optional tunnel insulator between graphene material layer 25 and the surface of the semiconductor layer 15) with the graphene material layer 25 operating as an electrical electrode to establish a potential on the surface of the semiconductor material 15 and to collect photogenerated carriers. The graphene material on semiconductor preferably forms a graphene material layer/semiconductor heterojunction (e.g., carrier collection region 20) that when properly biased allows photogenerated electrons (or holes) within a P-type (N-type) semiconductor to transport from the semiconductor material 15 to the graphene material layer electrode 40 and result in a current from the electrons (holes) flowing in the graphene electrode 40 to a bias supply. The graphene material layer/semiconductor heterojunction (e.g., carrier collection region 20) may also provide a controlled surface potential on the surface of a semiconductor without a dead layer (e.g., the dead layer may prevent the photogenerated carriers from transporting to an appropriate electrode).

For the case of an ohmic metal contact to the semiconductor layer, a PiN “like” photodiode is established with the graphene/semiconductor heterojunction (e.g., carrier collection region 20) reverse biased. For the case of a Schottky metal contact to the semiconductor layer, the graphene/semiconductor heterojunction (e.g., carrier collection region 20) is reverse biased and the Schottky metal/semiconductor junction is forward biased.

Use of the graphene material layer 25 on the semiconductor layer 15 as an electrode 40 of the UV/EUV photodetector 10 allows the graphene material layer 25 to be very thin (as thin as a single sheet of graphene) and only absorb a small percentage of the incident light. For example, the graphene material layer 25 may comprise of one graphene sheet. The graphene sheet may absorb only 2.3 percent of the incident light and thus approximately 97 percent of the UV/EUV light will be absorbed in the semiconductor (e.g., photodetector body layer 15). EUV light is absorbed in approximately 10 nm of the semiconductor material (e.g., photodetector body layer 15). A single sheet of graphene is approximately 0.3 nm thick and thus, a high percentage of the EUV light may transit through the graphene material 25 into the semiconductor layer 15 without absorbing in the graphene material electrode 40. The graphene material layer electrode 40 may comprise of one or more graphene sheets but is in one example, only one sheet of graphene is used as an electrode for the EUV photodetector.

The sheet resistance of one sheet of graphene is approximately 750 ohms/square. The semiconductor material (e.g., photodetector body layer 15) may be silicon carbide, gallium nitride, aluminum gallium nitride, indium aluminum nitride, aluminum nitride, silicon, gallium arsenide, indium phosphide, diamond, zinc oxide, magnesium zinc oxide, and other appropriate material. The semiconductor material may be selected based on properties such as bandgap energy, absorption coefficient at the wavelength of interest, surface state density, material defects, photocarrier recombination lifetime, whether the surface has positive or negative fixed charge, electron-hole generation lifetime, etc. One criteria that is often important is that the bandgap of the semiconductor material.

One example criterion for the UV/EUV is that the UV/EUV photodetector device 10g be solar blind. In this case, the UV/EUV photodetector device 10g should not be responsive to light with wavelengths longer than approximately 280 nm wavelength. An example semiconductor material to implement a solar blind UV or EUV photodetector device 10g is AlGaN with a bandgap of approximately 4.2 eV. Other semiconductor materials such as InAlN are also appropriate for a solar blind EUV photodetector device 10g. The AlGaN and InAlN semiconductor material may be formed by the epitaxial growth of AlGaN or AlInN on a GaN epitaxial layer or GaN/AlGaN, or GaN/AlN epitaxial layer on a substrate 30 such as a silicon, silicon carbide, sapphire, or AlN substrate 30. Another reason for choosing the semiconductor material is to have a wide bandgap to have a low generation lifetime and thus a low leakage current. Silicon carbide, gallium nitride, and aluminum gallium nitride are wide bandgap materials with low generation lifetime and thus low leakage current.

Another factor to consider is a passivation layer with low surface state density on the surface of the semiconductor so that there is a low leakage current. Also, another factor is that there not be dead layers formed within the photodetector that may impede the transport of photogenerated carriers to the graphene electrode. Moreover, the graphene should form a low leakage junction (heterojunction) with the semiconductor material. This is of particular note if there is an electrical bias established between the graphene material electrode and the semiconductor material. The graphene on semiconductor photodetector may be operated without applying a bias voltage between the graphene material electrode and the semiconductor material, however, it generally the case that a reverse bias be established between the graphene material electrode and the semiconductor.

For the case that the semiconductor material is P-type (N-type), this would mean applying a positive voltage to the graphene material electrode relative to the semiconductor bias to create a depletion layer in the semiconductor material and accelerate photogenerated electrons toward the graphene electrode and photogenerated holes into the semiconductor material. For the case that the semiconductor material is N-type, this would mean applying a negative voltage to the graphene material electrode relative to the semiconductor bias to create a depletion layer in the semiconductor material and accelerate photogenerated holes toward the graphene electrode and photogenerated electrons into the semiconductor material. The graphene material on semiconductor may for a rectifying contact that allows the application of a reverse bias between the graphene material electrode and the semiconductor. The offset in potential of the conduction band minimum of the emitter region material or collector region material and the conduction band minimum of the base graphene material layer 25 may be estimated by using the difference in electron affinity of the two material systems. Table I shows the estimated conduction band offset between graphene and a semiconductor estimated from the electron affinity difference.

TABLE I
Electron Affinity

| | Electron Affinity | | Conduction Band Offset to Graphene | |
|---|---|---|---|---|
| Graphene | 4.5 | eV | | |
| CdSe | 4.95 | eV | −0.45 | eV |
| InAs | 4.9 | eV | −0.4 | eV |
| SnO₂F | 4.8 | eV | −0.3 | eV |
| InSb | 4.59 | eV | −0.09 | eV |
| ZnO | 4.5 eV or 4.35 eV | | 0.0 eV or 0.15 eV | |
| BN | 4.5 | eV | 0.0 | eV |
| CdTe | 4.5 | eV | 0.0 | eV |
| CdS | 4.5 | eV | 0.0 | eV |
| In₂O₃Sn | 4.5 | eV | 0.0 | eV |
| InGaN | 4.1 eV to 4.59 eV | | −0.4 | eV |
| InAsP | 4.38 eV to 4.9 eV | | −0.4 eV to 0.12 eV | |
| InP | 4.38 | eV | 0.12 | eV |
| InGaAs | 4.1 eV to 4.9 eV | | −0.4 eV to 0.4 eV | |
| InAlAs | 4.1 eV to 4.9 eV | | −0.4 eV to 0.4 eV | |
| InGaSb | 4.1 eV to 4.59 eV | | −0.09 eV to 0.4 eV | |
| InN | | | | |
| InAsN | | | | |
| Diamond | 4.2 eV to 4.5 eV | | 0.0 eV to 0.3 eV | |
| GaN | 4.1 eV or 4.3 eV | | 0.2 eV or 0.4 eV | |
| GaAs | 4.07 | eV | 0.43 | eV |
| Silicon | 4.05 eV or 4.29 eV | | 0.45 | eV |
| 4H—SiC | 4.05 | eV | 0.45 | eV |
| GaSb | 4.05 | eV | 0.45 | eV |
| Germaninum | 4.0 | eV | 0.5 | eV |
| AlP | 3.98 | eV | 0.52 | eV |
| ZnS | 3.9 | eV | 0.6 | eV |
| GaP | 3.8 | eV | 0.7 | eV |
| AlSb | 3.65 | eV | 0.85 | eV |
| AlAs | 3.5 | eV | 1.0 | eV |
| AlN | 0.6 | eV | 3.9 | eV |

Graphene Material Layer Heterojunction with SiC

For example, for the case of graphene on 4H—SiC, the estimated conduction band offset is approximately 0.45 eV. Since the bandgap of 4H—SiC is 3.26 eV, the estimated valance band offset between the graphene material and the SiC valance band is approximately 2.81 eV. The graphene on SiC may thus be approximately treated as an Schottky or Schottky “like” junction with approximately a 0.45 barrier for electron injection from the graphene into the 4H—SiC semiconductor or a 2.81 barrier for injection of holes from the graphene material into the 4H—SiC. These barrier heights may be different then the simple estimate above when traps at the graphene material/semiconductor interface, image potential, and other mechanisms are taken into account. Moreover, there will be different potential barrier values for other semiconductors.

It has been experimentally determined that a low leakage reverse bias graphene material to 4H—SiC junction may be formed for the case that the 4H—SiC semiconductor material is P-type; i.e., a large positive voltage may be applied to the graphene material electrode relative to the 4H—SiC semiconductor material and still have low leakage current. This is consistent with the large potential barrier for the hole injection from the graphene material into the P-type 4H—SiC material. For the case of graphene material on N-type 4H—SiC, the leakage current is higher and this is also consistent with there being a smaller potential barrier for electron injection from the graphene material into the N-type 4H—SiC.

In the case of graphene material on P-type 4H—SiC, a very large reverse bias may be applied and thus there is the potential for avalanche gain for photogenerated carrier in the depletion layer in the P-type 4H—SiC. Thus, an avalanche graphene material on semiconductor UV or EUV photodetector is possible. It may be the case there is a thin oxide material layer between the graphene material and the semiconductor material. In one example, this thin oxide material not be sufficiently thin to not impede the flow of photogenerated current to the graphene material electrode (the thin oxide is a tunnel insulator). The thin oxide layer may, in some cases, be a benefit to reduce leakage current. The thin oxide material may be a native oxide that is on the surface of the semiconductor when a graphene material is transferred and bonded to a semiconductor or may be formed from the growth of graphene material on a semiconductor.

UV/EUV Photodetector Device Examples

Assuming that the graphene material layer electrode is on the front surface of the semiconductor layer and that the UV/EUV illumination is into the front surface of the semiconductor layer, the main variation in the UV/EUV photodetector device described below are: (1) Frontside metal contact versus backside metal contact to semiconductor layer; (2) Ohmic metal contact versus Schottky metal contact to the semiconductor layer; (3) Etched mechanical support substrate on the backside versus etched mechanical support substrate wafer bonded to frontside of semiconductor layer; (4) Smart cut versus etched substrate versus laser ablation substrate removal; and (5) Isolation between laterally adjacent photodetector diodes by deep level ion implantation to create semi-insulating layer, formation of opposite dopant in the isolation region to semiconductor layer, epitaxial regrowth in the isolation region, selective epitaxial growth of photodetector epitaxial layer with separation between epitaxial layers, photoelectrochemical etched trench in the isolation region, or reactive ion etching (RIE) etched trench in the isolation region, and also doping concentration incorporated at the front or back surface to prevent inversion layer at the front or back surfaces.

In the ohmic metal contact versus Schottky metal contact to the semiconductor layer approach, a higher dopant concentration in a semiconductor is used to achieve ohmic contact. Also, the metal contact is typically alloyed. In some cases, ohmic contact may be made without annealing at high temperatures; i.e., non-alloyed contacts. Schottky metal contacts are typically made to low dopant concentration semiconductor surface. The Schottky metal contact may be naturally isolated if there are no surface inversion, two-dimensional electron gas (2DEG), or two-dimensional hole gas (2DHG) conduction between laterally separated photodiode pixels.

In the etched mechanical support substrate on the backside or the frontside of semiconductor layer approach, the mechanical support substrate will be recessed (etched) in selected regions to the surface of the semiconductor layer or graphene material layer surface to allow UV/EUV light to illuminated the semiconductor layer and create photocarriers in the semiconductor layer. There will be ribs of the mechanical support substrate remaining attached to the semiconductor layer so that mechanical support is provided to the semiconductor layer. There may be two alternatives for the mechanical support substrate approach: (A) mechanical substrate on the frontside, and (B) mechanical substrate on the backside.

In the mechanical substrate on the frontside approach, the mechanical support substrate comprises a wafer bonded to the graphene material layer surface, optionally using a material layer that is deposited on the graphene surface and then chemical-mechanical polishing (CMP) to facilitate wafer bonding or alternately polymer layers, adhesive layers, spin-on-glass, metal layers to facilitate bonding of support substrate to the semiconductor layer.

In the mechanical substrate on the backside approach, III-Nitride layers are typically grown on a substrate that is not a III-Nitride material. The substrate may be etched in selected locations recessed in selected regions to the back surface of the III-Nitride semiconductor layer surface to allow UV/EUV light to illuminated the semiconductor layer and create photocarriers in the semiconductor layer. There will be ribs of the mechanical support substrate remaining attached to the semiconductor layer so that mechanical support is provided to the semiconductor layer.

In the smart cut versus etched substrate or laser ablation substrate removal approach, the front surface of the semiconductor layer is wafer bonded to a support substrate during the smart cut versus etched substrate or laser ablation substrate removal processes.

In the isolation by deep level ion implantation approach, an opposite dopant to the semiconductor layer, or a trench with a doping device is incorporated to prevent an inversion layer at the front or back surfaces.

There are various approaches to provide isolation between pixels for a frontside illuminated/frontside contacted UV/EUV photodetector. Here, one of the goals is to prevent an inversion layer from forming at the surface that could cause a leakage path between pixel elements. In this regard, a high dopant concentration at the surface may be used to prevent the inversion layer at the surface.

The isolation of the epitaxial layer doped regions between pixel elements may occur by implantation of an opposite dopant as the epitaxial layer in the isolation regions; formation of a P-well (or N-well) for the photodetector region by ion implantation or diffusion in background N-type (P-type) epitaxial material; RIE, inductively coupled plasma (ICP) etch, or ion mill etch of a trench and passivation of side walls of the trench; a photoelectrochemical etch of a trench between laterally separated photodiode pixels; selective epitaxial growth of laterally separated P-type (N-type regions); implantation of deep level traps to implement a semi-insulating layer; high dopant concentration at the surface to prevent the inversion layer at the surface; and potential barrier isolation. Furthermore, a high dopant concentration at the surface may be used to prevent formation of the inversion layer at the surface.

Frontside Illuminated/Frontside Contact UV/EUV Photodetector

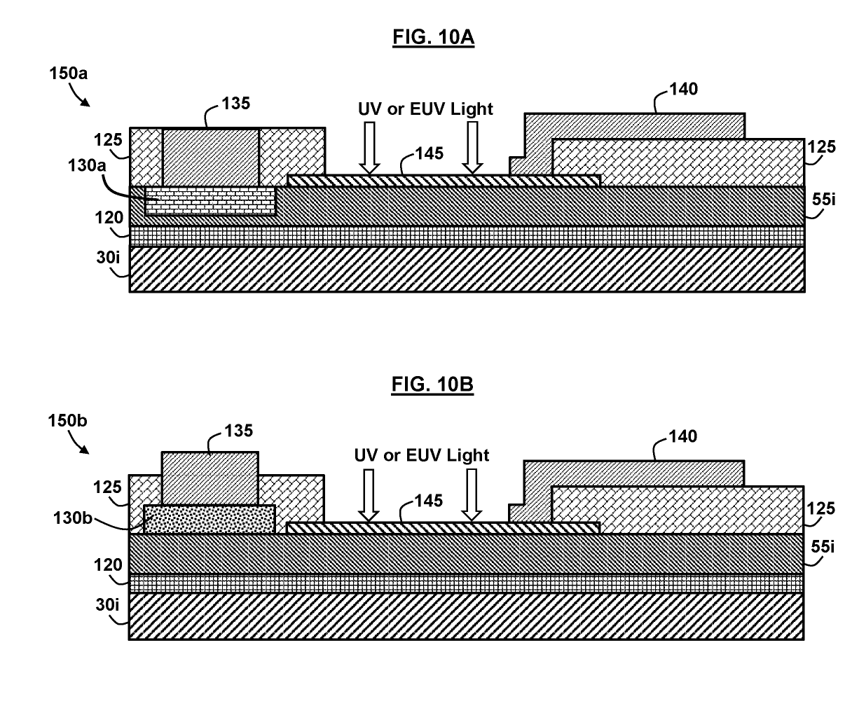

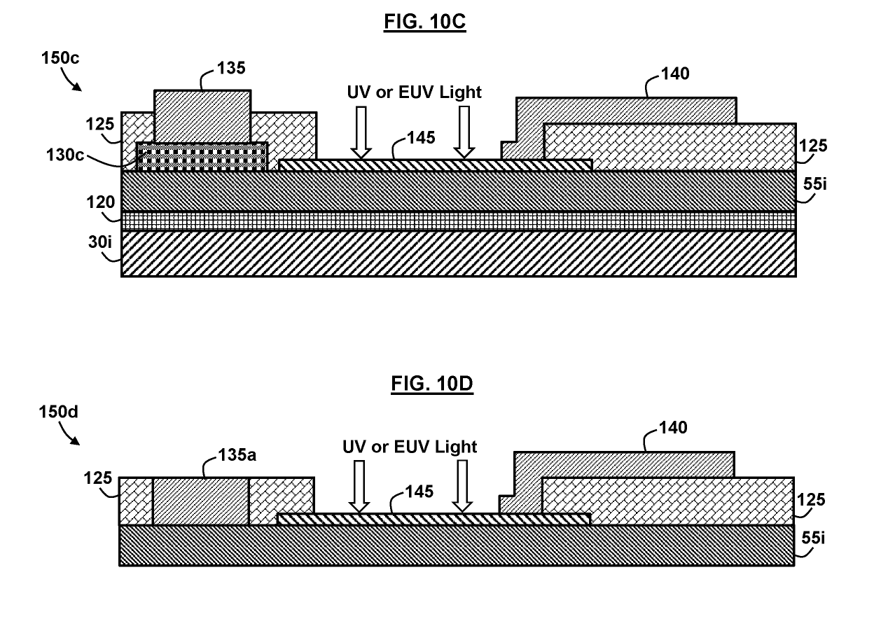

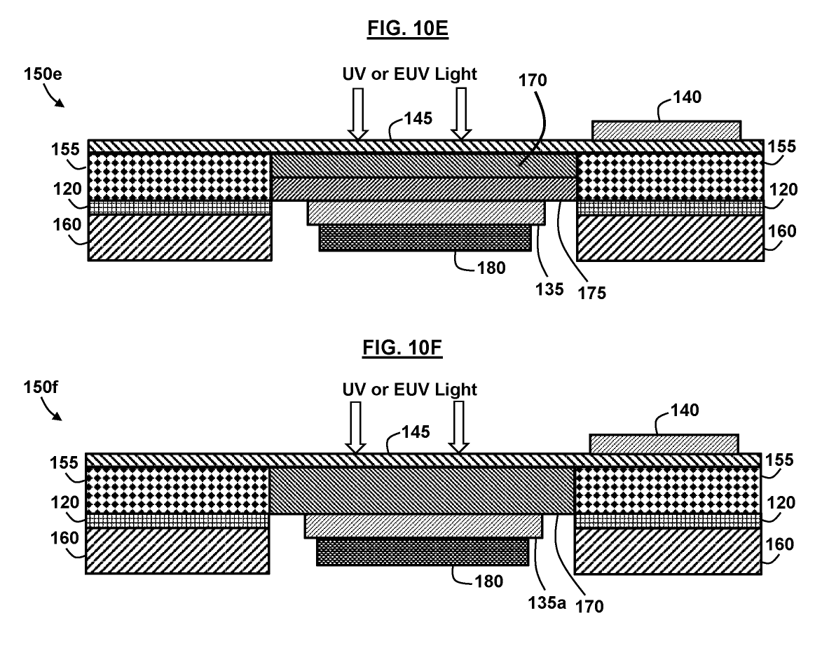

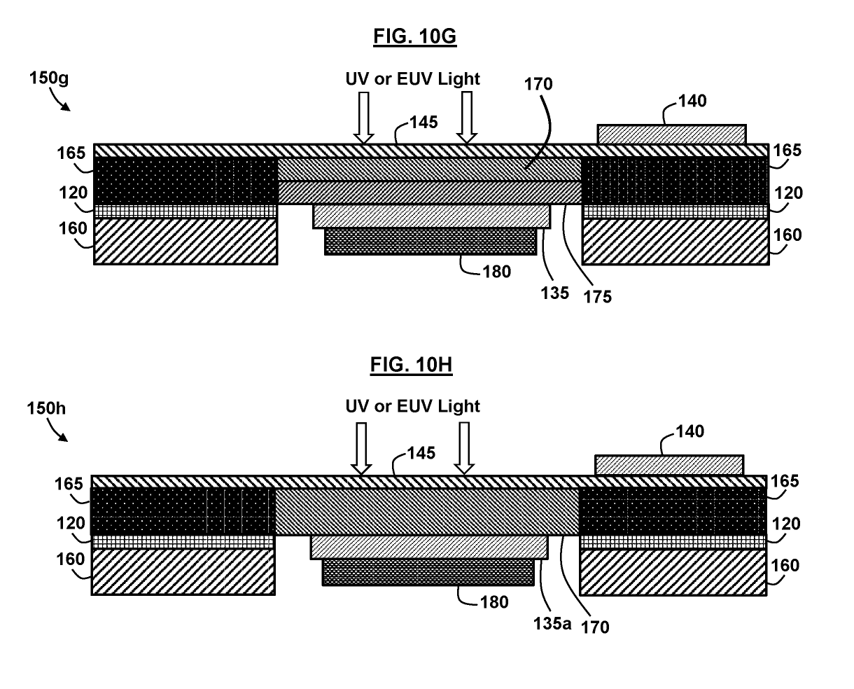

Various configurations of the frontside illuminated/frontside contacted UV/EUV photodetector approach are illustrated in FIGS. 10A through 10H, with reference to FIGS. 1 through 9.

FIG. 10A illustrates a frontside illuminated/frontside contacted UV/EUV photodetector device 150a with implanted P+ (N+) region 130a alloyed or non-alloyed ohmic metal contact to a semiconductor layer 55i. In device 15a, an ion implant high dopant concentration for ohmic contact is made and then an anneal is performed to activate the implanted dopant. A graphene material layer 145 is either epitaxially grown on a semiconductor substrate such as SiC, or the graphene material layer 145 is grown on a metal substrate and transferred and bonded to a semiconductor epitaxial layer 120 on a substrate 30i, or is grown at the interface of a metal such as nickel and a semiconductor layer surface. A photostep is performed to mask the graphene material layer 145 so that the graphene material layer 145 is removed (etched) outside of a defined area. An optional passivation dielectric layer 125 may be deposited. A photostep is performed to form ohmic metal 135 on the ion implanted high dopant concentration P+ (N+)-type layer 130a. An alloy anneal step is performed if needed. A photostep is performed to define the ohmic metal 140 to the graphene material layer 145.

FIG. 10B illustrates a frontside illuminated/frontside contacted UV/EUV photodetector device 150b with epitaxial P+ (N+) layer 130b with recess etch alloyed or non-alloyed ohmic metal contact to a semiconductor layer 55i. In this process, a P+ (N+) epitaxial layer 130b is grown on the surface of the semiconductor layer 55i. A recess etch is performed to etch through the P+ (N+) layer 130b. A graphene material layer 145 is epitaxially grown on the recess etched area or is transferred and bonded to the recess etch surface. In one example, the graphene material layer 145 conforms to the semiconductor surface recess etched surface and good bonding occurs between the graphene material layer 145 and the recess etched semiconductor layer 55i. An optional passivation dielectric layer 125 may be deposited. A photostep is performed to form ohmic metal 135 on the ion implanted high dopant concentration P+ (N+)-type layer 130b. An alloy anneal step is performed if needed. A photostep is performed to define the ohmic metal 140 to the graphene material layer 145.

FIG. 10C illustrates a frontside illuminated/frontside contacted UV/EUV photodetector device 150c with a regrown epitaxial P+ (N+) layer 130c alloyed or non-alloyed ohmic metal contact to a semiconductor layer 55i. In this process, graphene 145 is formed on the surface of the semiconductor layer 55i and is defined. Then, a high dopant concentration epitaxial P+ (N+) epitaxial layer 130c is selectively grown in openings in a dielectric. An optional passivation dielectric layer 125 is deposited. A photostep is performed to form ohmic metal 135 on the ion implanted high dopant concentration P+(N+)-type layer 130c. An alloy anneal step is performed if needed. A photostep is performed to define the ohmic metal 140 to the graphene material layer 145.

FIG. 10D illustrates a frontside illuminated/frontside contacted UV/EUV photodetector device 150d with a Schottky metal contact 135a to a semiconductor layer 55i. For the case of a Schottky metal contact 135a to the semiconductor layer 55i, it is not necessary to have a high P+ (N+) dopant concentration. Thus, the process is similar to the device 150a shown in FIG. 10A except that it is not necessary to form an ion implanted P+ (N+) layer 130a into the semiconductor layer 55i.

Another embodiment (not shown) includes a frontside illuminated/frontside contacted UV/EUV photodetector device non-alloyed P+ (N+) ohmic contact to a semiconductor layer 55i. Here, a non-alloyed contact may be made to the nitrogen-face of III-Nitride epitaxial layers or to high dopant P+ (N+) regions.

Frontside Illuminated/Backside Contacted UV/EUV Photodetector with Etched Mechanical Support on the Backside

FIG. 10E illustrates a frontside illuminated/backside ohmic contact UV/EUV graphene on a semiconductor photodetector device 150e using a selected area etch of a mechanical support substrate 160 and a proton or deep level implant isolation. The device 150e may use a III-nitride epitaxial layer 170 grown on a silicon substrate that may be etched. The III-nitride epitaxial layers may be grown so that a P+ (N+) epitaxial layer 175 is at the bottom surface (e.g., surface closest to the substrate 160) of the III-nitride epitaxial layer that will aid in facilitating ohmic contact. One approach to achieve electrical isolation between laterally separated UV/EUV photodetector pixels is to perform an ion implantation of atoms such as protons or oxygen that create deep level traps 155. A graphene material layer 145 may be formed on the surface of the III-nitride epitaxial layer 170 by transferring and bonding a graphene layer 145 formed on a metal surface to the surface of the III-nitride material 170. The graphene 145 may also be formed on the surface of the III-nitride material 170 by depositing a metal such as nickel or iron on the III-nitride surface, forming a carbon material that precipitates into the metal by exposing to methane or ion implanting carbon into the metal, and then rapidly cooling to have the nickel precipitate out of the interior of the metal to the interface between the metal and the III-nitride semiconductor. An optional temporary handle wafer may be attached to the front surface of the device 150e to provide additional mechanic support during the indium bump process. The mechanical support substrate 160 on the backside is then etched to the III-nitride material in selected locations, leaving a grid of the substrate 160 remaining in the regions between the laterally separated photodetector pixels. The exposed III-nitride nucleation layer 120 is etched. An ohmic metal 135 is next deposited so that it contacts the P+ (N+) III-nitride material 175. An alloy anneal is optionally performed. A non-alloy ohmic contact 140 may be included in the exposed back surface of the III-nitride material. An indium bump 180 is formed on the surface of the ohmic metal 135 and the detector is bumped to a readout integrated circuit (not shown). The optional temporary handle wafer is then removed.

FIG. 10F illustrates a frontside illuminated/backside Schottky contact UV/EUV graphene on semiconductor photodetector device 150f using an etched mechanical support. The process for forming device 150f is similar to the process for forming device 150e of FIG. 10E except that there are no P+ (N+) doped regions 175 at the backside of the substrate 160 so that a Schottky contact 135a may be formed to the back surface of the III-nitride epitaxial layer 170.

FIG. 10G illustrates a frontside illuminated/backside ohmic contact UV/EUV graphene on a semiconductor photodetector device 150g using an etched mechanical support substrate 160 and isolation impurity doping opposite detector doping. The process for forming device 150g is similar to the process for forming device 150e of FIG. 10E except that the isolation between laterally separated photodetector pixels is made by an N-type doped region 165, a trench, or epitaxially regrown N-type (P-type) material. The N-type (P-type) doped region 165 between laterally separated photodetector pixels may be made by N-type (P-type) dopant ion implantation or alternately the implantation of P-type (N-type) dopant to form a P-well (N-well) in the III-nitride material layers 170 that are N-type (P-type).

The N-type (P-type) doped region 165 may also be made by etching P-type (N-type) material and then re-growing N-type (P-type) material in the etch regions followed by CMP polish. The trench isolation may be performed by reactive ion etching or alternately photoelectrochemical etching. The photoelectrochemical etching will have the least material damage and may result in the lowest leakage current. An alternate approach to from trench isolation between laterally separated photodetector pixels is to selectively grow P-type regions with narrow separation from adjacent P-type (N-type) regions on the AlN nucleation layer on a silicon substrate 160. The trench regions may be filled with oxide and then a metal layer deposited to connect graphene material layer 145 on top of each of the P-type (N-type) III-Nitride regions to the graphene material layer 170 in adjacent P-type (N-type) III-Nitride material regions. The remainder of the process is similar as described with respect to the device 150e of FIG. 10E.

FIG. 10H illustrates a frontside illuminated/backside Schottky contact UV/EUV graphene on a semiconductor photodetector device 150h using a selected area etch of a mechanical support substrate 160 and an isolation impurity doping opposite detector doping. The process for forming device 150h is similar to the process for forming device 150g of FIG. 10G except that there are no P+ (N+) doped regions 175 at the backside of the substrate 160 so that a Schottky contact 135a may be formed to the back surface of the III-nitride epitaxial layer 170.

Frontside Illuminated/Backside Contacted UV/EUV Photodetector with Etched Mechanical Support on Frontside

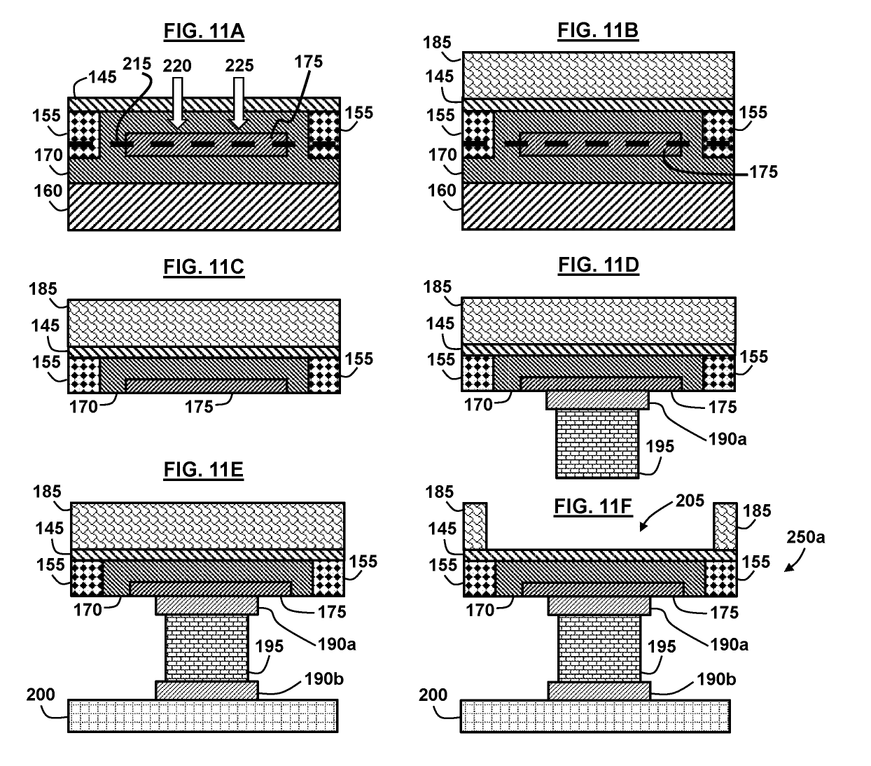

FIGS. 11A through 11F, with reference to FIGS. 1 through 10H, illustrate sequential manufacturing steps for forming a frontside illuminated/backside ohmic contact UV/EUV graphene on a semiconductor photodetector device 250a using a smart cut process into a P-type semiconductor layer 170. In the smart cut approach, a surface semiconductor layer 170 may be split from a substrate 160 by implanting a hydrogen ion implant (or a hydrogen ion implant in combination with a helium implant) 220 and then using a process of annealing to cause hydrogen gas pressure buildup that causes crystal lattice splitting. Alternately, a water jet impinging on the implanted region from the side of the wafer or a knife edge incident on the implant layer may split a surface semiconductor layer 170 from the semiconductor substrate 160. Beginning with FIG. 11A, in the smart cut approach, an optional retrograde P+-type (N+-type) ion implant 225 is made through a graphene layer 145 into a P-type (N-type) semiconductor epitaxial layer 170 to a selected depth 215 so that the surface of the P-type (N-type) semiconductor epitaxial layer 170 remains P-type (N-type). Typical P-type semiconductor materials include P-type SiC, GaN, AlGaN, AlN, InAlN, InGaAlN, MgZnO, and ZnO. An anneal is next performed to activate the optional P-type retrograde ion implant 225. A hydrogen ion implant (or hydrogen+helium ion implant) 220 is next performed so that the peak of the implant is at a depth that is at approximately middle depth 215 of the retrograde P-type ion implant 225. The front surface of the P-type (N-type) semiconductor epitaxial layer surface 170 is then wafer bonded to a support substrate 185, which may comprise silicon, as indicated in FIG. 11B. There may be materials on the graphene surface 145 such as plasma enhanced chemical vapor deposition (PECVD) silicon oxide that is CMP polished to facilitate wafer bonding. The silicon/SiC pair is then heated, as provided in FIG. 11C, to cause the SiC substrate 160 to split at the depth 215 of the location of the hydrogen ion implant 225. An optional CMP polish, oxidation step, or anneal process may be performed to reduce the damage at the smart cut surface.

The smart cut process for splitting a surface semiconductor layer 170 from a semiconductor substrate 160 is especially appropriate for the case of a SiC epitaxial layer and SiC substrate 160 since it is very difficult to achieve a thin single crystal silicon carbide layer expect by the smart cut process. The smart cut process may also work for the case of AlGaN or GaN epitaxial layers on a substrate 160 and especially for the case of AlGaN or GaN epitaxial layers on a silicon substrate 160. The smart cut ion implant may be performed so that the semiconductor layer 170 splitting occurs within the AlGaN or GaN epitaxial layer materials or within the hydrogen ion implant 220 and may be performed so that the semiconductor layer 170 splitting occurs within the silicon substrate 160. The silicon substrate 160 may then be etched back to the AlN nucleation layer which may be etched, and further etching into the AlGaN or GaN epitaxial layer may be performed if desired.

Isolation between laterally adjacent detector elements, assuming a P-type (N-type) semiconductor layer 170, may be obtained by ion implant of an N-type (P-type) dopant layer, etching a trench and passivating side wall of trench 155, ion implanting a deep level trap to convert the P-type (N-type) semiconductor region 170 into a semi-insulating region, recessing the semiconductor layer 170 and then epitaxially growing the opposite type doped material layer 175 in the recess area followed by a CMP polish, or alternately, implanting a P-type (N-type) well region that extends from the surface to beyond the smart cut depth 215 and optional P+ (N+) retrograde ion implant layer with a peak at approximately the smart cut depth 215 into an N-type (P-type) semiconductor layer. If a Schottky backside contact is used, there may be a natural isolation between laterally adjacent detector elements. The ion implantation steps for isolating may be performed prior to growth of the graphene material layer 145.

Due to a fixed positive charge in native oxide and deposited oxide material, there may be a surface inversion layer on the back surface of the UV/EUV photodetector. The N-type (P-type) material between laterally separated detectors will typically have an accumulated surface and thus, there will not be a surface inversion layer conduction path between laterally separated detector elements. As shown in FIG. 11D, an ohmic metal layer 190a is then deposited and patterned so that the metal resides within the outside boundary of the P-type region 170 on the smart cut surface. This ohmic metal contact 190a will enable a front side illuminated graphene 145 on semiconductor UV/EUV PiN “like” photodetector with backside ohmic contact. Alternately, a Schottky metal layer is then deposited and patterned so that the metal resides within the outside boundary of the N-type (P-type) region on the smart cut/CMP polished surface. This Schottky metal contact will enable a front side illuminated graphene on semiconductor UV/EUV graphene/semiconductor/metal photodetector with backside Schottky contact.

The graphene material/semiconductor/metal photodetector contact will operate in the mode with the graphene material layer/semiconductor junction is reverse biased and the Schottky metal/semiconductor junction is forward biased. An anneal is then formed to form an ohmic contact to the SiC material. An indium bump device 195 is next made and the UV/EUV photodetector array is bump bonded with a contact 190b to a silicon readout circuit 200, as shown in FIG. 11E.

The next step shown in FIG. 11F is that the silicon support substrate 185 may be optionally thinned and then a portion of the silicon support substrate 185 is etched to expose the surface of the graphene layer 145 while leaving a portion of the silicon support substrate 185 on the surface of the graphene 145 to act as front side mechanical support for the thin graphene on smart cut SiC surface 170. A combination of plasma etching and chemical etching may be used to etch the silicon support substrate 185 to create the opening 205 to the surface of the graphene 145 with the chemical etch used to etch the silicon support 185 on the graphene 145 without damaging the graphene material 145. An etch stop layer (not shown) such as a thin oxide layer may be positioned between the silicon support substrate 185 and the graphene layer 145 to act as an etch stop to the graphene layer 145. It may be desirable that there be electrical connection between the silicon support material 185 and the graphene material layer 145 to provide an electrical potential to the silicon support substrate 185. An ohmic contact (not shown) may be made to the silicon support substrate 185 to make an electrode connection to the silicon support substrate 185 that further provides an electrical connection to the graphene material layer 145.

Another embodiment provides a frontside illuminated/backside ohmic contact UV/EUV graphene on a semiconductor photodetector device using a smart cut process into a N-type (P-type) semiconductor layer and forming a p-well. This process is the same as the process described in FIGS. 11A through 11F except that this process implants a P-type well region that extends from the surface to beyond the smart cut depth 215 and an optional P++ retrograde ion implant layer with a peak at approximately the smart cut depth 215 is formed into an N-type semiconductor layer. An alternate approach to obtain a P-type well in the case of SiC is to diffuse boron into the SiC layer. A shallow boron may be implanted into the SiC and then diffused into SiC using an anneal temperature of approximately 1700-1800° C. The surface of the SiC may be CMP polished after the high temperature anneal to remove the shallow P-type implant damage region. Isolation between laterally separated photodetector elements is achieved by the presence of the unimplanted N-type (P-type) semiconductor layer.

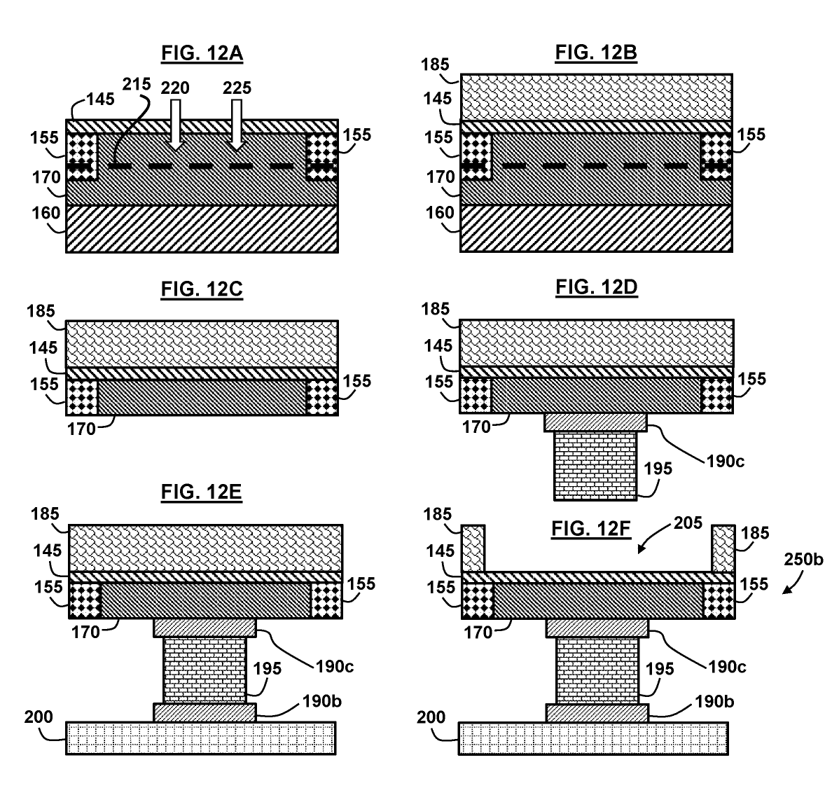

FIGS. 12A through 12F, with reference to FIGS. 1 through 11F, illustrate sequential manufacturing steps for forming a frontside illuminated/backside Schottky contact UV/EUV graphene on a semiconductor photodetector device 250b using a smart cut process into a P-type (N-type) semiconductor layer 170. This process is the same as process described with respect to device 250a in FIGS. 11A through 11F except that a Schottky metal contact 190c is formed to the backside of the smart cut surface (optionally polished or oxidized to reduce smart cut damage) is made. Also, the P+-type (N+-type) retrograde ion implant region 175 is also not used for the case of the backside Schottky contact photodetector device 250b.

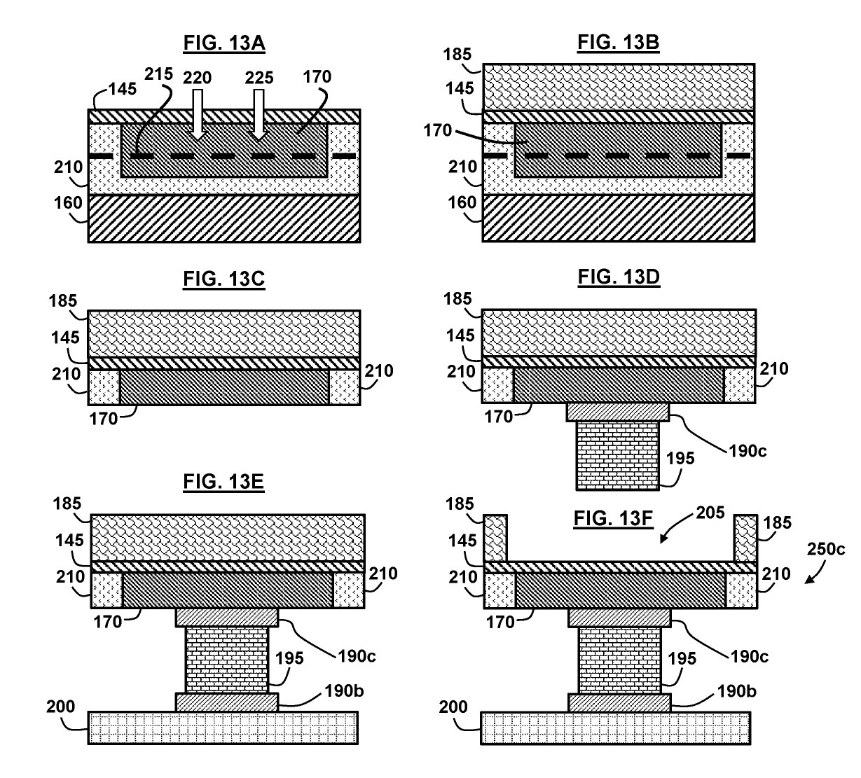

FIGS. 13A through 13F, with reference to FIGS. 1 through 12F, illustrate sequential manufacturing steps for forming a frontside illuminated/backside Schottky contact UV/EUV graphene on a semiconductor photodetector device 250c using a smart cut process into a N-type (P-type) semiconductor layer 210 and forming a P-well. This process is the same as the process described with respect to the frontside illuminated/backside ohmic contact UV/EUV graphene on a semiconductor photodetector using a smart cut process into a N-type (P-type) semiconductor layer and forming a P-well described above except that a Schottky metal contact 190c is formed to the backside of the smart cut surface (optionally polished or oxidized to reduce smart cut damage) is made. The P+-type (N+-type) retrograde ion implant region 175 is also not used for the case of the backside Schottky contact photodetector device 250c.

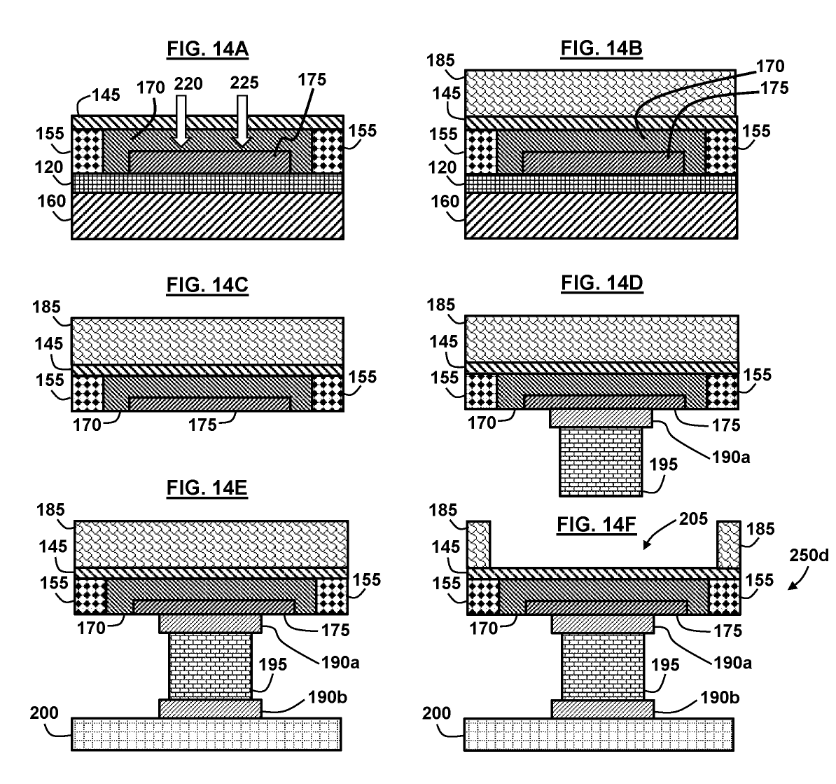

FIGS. 14A through 14F, with reference to FIGS. 1 through 13F, illustrate sequential manufacturing steps for forming a frontside illuminated/backside ohmic contact UV/EUV graphene on a semiconductor photodetector device 250d using a substrate etch process or laser ablation process for a P-type (N-type) semiconductor layer 170. This process is the similar to the process for device 250a in FIGS. 11A through 11F described above except that the process will typically be used for the case of III-Nitride epitaxial layers grown on a substrate 160 that may be removed from the substrate 160 by etching the substrate 160 away or by illuminating the epitaxial layer/substrate interface with a laser to ablate a portion of the material or covalent bonds at the epitaxial layer/substrate interface to allow the epitaxial layers to separate from the substrate 160. A wafer bonded front side support substrate 185 is used similar to the process described in FIGS. 11A through 11F.

Isolation between laterally adjacent detector elements, assuming a P-type (N-type) semiconductor layer, may be obtained by ion implant of an N-type dopant layer 155, etching a trench and passivating side wall of trench, ion implanting a deep level trap to convert the P-type semiconductor region 170 into a semi-insulating region, recessing the semiconductor layer to the nucleation layer 120 and then epitaxially growing the opposite type doped material layer in the recess area followed by CMP polish, or alternately, implanting a P-type (N-type) well region that extends from the surface to beyond the smart cut depth and optional P+ (N+) retrograde ion implant layer 175 with a peak at approximately the smart cut depth into an N-type (P-type) semiconductor layer. If a Schottky backside contact is used, there may be a natural isolation between laterally adjacent detector elements. The ion implantation steps for isolating may be performed prior to graphene material layer 145 growth or transfer/bond process. Due to fixed positive charge in native oxide and deposited oxide material, there may be a surface inversion layer on the back surface of the UV/EUV photodetector device 250d. The N-type material between laterally separated detectors will typically have an accumulated surface and thus, there will not be a surface inversion layer conduction path between laterally separated detector elements. For III-Nitride materials, the exposed surface after the substrate 160 etch and nucleation layer 120 etch process will be a nitrogen-face material layer. It is often the case that a non-alloyed ohmic contact may be made to the nitrogen-face III-Nitride materials. The process for forming ohmic contact metal 190a, indium bump bond 195, bonding to a readout integrated circuit 200, and etching the silicon support substrate 1850 in selected regions 205 to provide mechanical support to the graphene material layer/semiconductor layer device 250d is the same as described in FIGS. 11A through 11F.

Another embodiment provides a frontside illuminated/backside ohmic contact UV/EUV graphene on a semiconductor photodetector using a substrate etch process or laser ablation process into a N-type semiconductor layer and forming a P-well (N-well). This process is the same as the process described with respect to the frontside illuminated/backside ohmic contact UV/EUV graphene on a semiconductor photodetector using a smart cut process into a N-type (P-type) semiconductor layer and forming a P-well described above except that the process implants a P-type (N-type) well region that extends from the surface to beyond the substrate surface and an optional P+ (N+) retrograde ion implant layer is deposited with a peak at approximately the nucleation layer surface into an N-type (P-type) semiconductor layer formed in III-Nitride epitaxial layers on a substrate. An alternate approach for forming a P-well (N-well) is recessing the N-type (P-type) semiconductor layer to the nucleation layer and then epitaxially growing the opposite type doped material P-type (N-type) layer in the recess area followed by CMP polish. Isolation between laterally separated photodetector elements is achieved by the presence of the unimplanted N-type semiconductor layer.

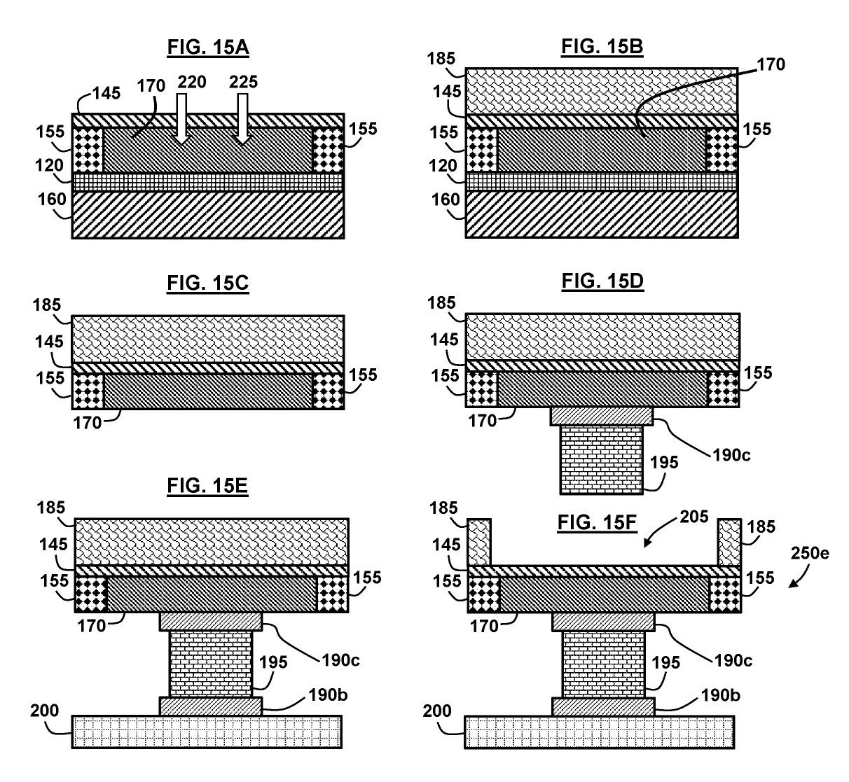

FIGS. 15A through 15F, with reference to FIGS. 1 through 14F, illustrate sequential manufacturing steps for forming a frontside illuminated/backside Schottky contact UV/EUV graphene on a semiconductor photodetector device 250e using a substrate etch process or laser ablation process into a P-type (N-type) semiconductor layer 170. This process is the similar to the process for device 250a in FIGS. 11A through 11F described above except that a Schottky metal contact 190c to the backside of the smart cut surface (optionally polished or oxidized to reduce smart cut damage) is made. The P+-type (N+-type) retrograde ion implant is also not used for the case of the backside Schottky contact photodetector device 250e.

Another embodiment provides a frontside illuminated/backside Schottky contact UV/EUV graphene on a semiconductor photodetector device using a substrate etch process or laser ablation process into a N-type semiconductor layer and forming a P-well (N-well). This process is the same as the process described in FIGS. 11A through 11F except that a Schottky metal contact is formed to the backside of the smart cut surface (optionally polished or oxidized to reduce smart cut damage) is made. The P+-type (N+-type) retrograde ion implant is also not used for the case of the backside Schottky contact.

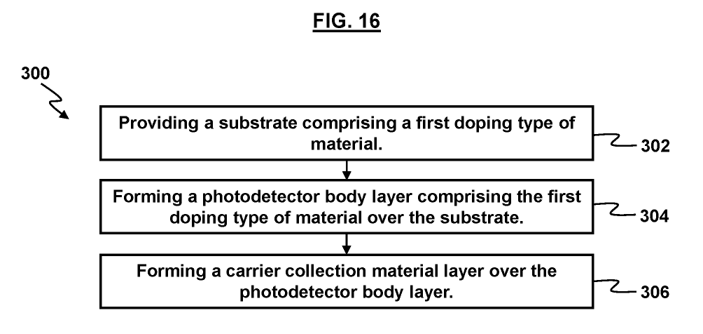

FIG. 16, with reference to FIGS. 1 through 15F, is a flow diagram illustrating a method 300 of forming an EUV photodetector 10, according to an embodiment herein. The method 300 may comprise providing (302) a substrate 30 comprising a first doping type of material; forming (304) a photodetector body layer 15 comprising the first doping type of material over the substrate 30, wherein the photodetector body layer 15 comprises a carrier collection region 20 and a potential barrier maximum level 14; and forming (306) a carrier collection material layer 25 over the photodetector body layer 15, wherein the carrier collection region 20 comprises a region between the potential barrier maximum level 14 and the carrier collection material layer 25, and wherein the potential barrier maximum level 14 comprises a height within the photodetector body layer 15 that prevents photogenerated carriers created at a depth deeper than the potential barrier maximum level 14 from transporting to the carrier collection region 20 and the carrier collection material layer 25. The method 300 may further comprise forming a bias semiconductor layer 55 comprising a second doping type of material over the substrate 30. The method 300 may further comprise depleting a doping concentration of any of the substrate 30, the photodetector body layer 15, and the bias semiconductor layer 55. The method 300 may further comprise adjusting the height of the potential barrier maximum level 14. The method 300 may further comprise configuring the substrate 30 to prevent transporting of photogenerated carriers to the thin carrier collection region 20.

According to the embodiments herein the graphene material 25 on a semiconductor layer (e.g., photodetector body layer 15) preferably forms a graphene material layer/semiconductor heterojunction (e.g., thin carrier collection region 20) that when properly biased allows photogenerated electrons (or holes) within a P-type (N-type) semiconductor to transport from the semiconductor material (e.g., photodetector body layer 15) to the graphene material layer 25 and electrode 40 and result in a current from the electrons (holes) flowing in the graphene electrode 40 to a bias supply. The graphene material layer/semiconductor heterojunction (e.g., thin carrier collection region 20) may also provide a controlled surface potential on the surface of a semiconductor without a dead layer (i.e., the dead layer may prevent the photogenerated carriers from transporting to an appropriate electrode). The use of a graphene material layer 25 on the semiconductor surface (e.g., photodetector body layer 15) as an electrode of the UV/EUV photodetector device 10 is able to allow the graphene material layer 25 to be very thin (i.e., as thin as a single sheet of graphene) and only absorb a small percentage of the incident light. The sheet resistance of one sheet of graphene is approximately 750 ohms/square.

The graphene sheet will absorb only 2.3 percent of the incident light and thus approximately 97 percent of the UV/EUV light will be absorbed in the semiconductor (e.g., photodetector body layer 15). EUV light is absorbed in approximately 10 nm of the semiconductor material (e.g., photodetector body layer 15). A single sheet of graphene is approximately 0.3 nm thick and thus, a high percentage of the EUV light may transit through the graphene into the semiconductor (e.g., photodetector body layer 15) without absorbing in the graphene material 25.

The foregoing description of the specific embodiments will so fully reveal the general nature of the embodiments herein that others may, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein may be practiced with modification within the spirit and scope of the appended claims.

What is claimed is:

1. An extreme ultraviolet (EUV) photodetector comprising:
a substrate comprising a first doping type of material;
a bias semiconductor layer comprising a second doping type of material and positioned over the substrate;
a photodetector body layer comprising the first doping type of material and positioned over the bias semiconductor layer, wherein the photodetector body layer comprises a carrier collection region and a potential barrier maximum level; and
a carrier collection material layer positioned over the photodetector body layer,
wherein the carrier collection region comprises a region between the potential barrier maximum level and the carrier collection material layer, and
wherein the potential barrier maximum level comprises a height within the photodetector body layer that prevents photogenerated carriers created at a depth deeper than the potential barrier maximum level from transporting to the carrier collection region and the carrier collection material layer.

2. The EUV photodetector of claim 1, further comprising:
an anode electrode contacting the photodetector body layer; and
a cathode electrode contacting the carrier collection material layer.

3. The EUV photodetector of claim 1, further comprising:
a first electrode contacting the bias semiconductor layer; and
a second electrode contacting the substrate.

4. The EUV photodetector of claim 1, wherein the bias semiconductor layer comprises a wide bandgap semiconductor material.

5. The EUV photodetector of claim 1, further comprising any of a stacked semiconductor layer, a doped semiconductor layer, an insulating layer, and a semi-insulating layer under the photodetector body layer.

6. The EUV photodetector of claim 1, wherein the substrate comprises any of a low doping concentration, a semi-insulating, and an insulating substrate.

7. The EUV photodetector of claim 1, wherein the carrier collection material layer comprises graphene.

8. An extreme ultraviolet (EUV) photodetector comprising:
a substrate comprising a first doping type of material;
a photodetector body layer comprising the first doping type of material and positioned over the substrate, wherein the photodetector body layer comprises a carrier collection region and a potential barrier maximum level; and
a carrier collection material layer positioned over the photodetector body layer,
wherein the carrier collection region comprises a region between the potential barrier maximum level and the carrier collection material layer, and
wherein the potential barrier maximum level comprises a height within the photodetector body layer that prevents photogenerated carriers created at a depth deeper than the potential barrier maximum level from transporting to the carrier collection region and the carrier collection material layer.

9. The EUV photodetector of claim 8, further comprising:
an anode electrode contacting the photodetector body layer; and
a cathode electrode contacting the carrier collection material layer.

10. The EUV photodetector of claim 8, further comprising a bias semiconductor layer comprising a second doping type of material and positioned over the substrate.

11. The EUV photodetector of claim 10, further comprising:
a first electrode contacting the bias semiconductor layer; and
a second electrode contacting the substrate.

12. The EUV photodetector of claim 10, wherein the bias semiconductor layer comprises a wide bandgap semiconductor material.

13. The EUV photodetector of claim 8, further comprising any of a stacked semiconductor layer, a doped semiconductor layer, an insulating layer, and a semi-insulating layer under the photodetector body layer.

14. The EUV photodetector of claim 8, wherein the substrate comprises any of a low doping concentration, a semi-insulating, and an insulating substrate.

15. The EUV photodetector of claim 8, further comprising any of a bandgap layer and an insulator layer between the substrate and photodetector body layer.

16. A method of forming an extreme ultraviolet (EUV) photodetector, the method comprising:
providing a substrate comprising a first doping type of material;
forming a photodetector body layer comprising the first doping type of material over the substrate, wherein the photodetector body layer comprises a carrier collection region and a potential barrier maximum level; and
forming a carrier collection material layer over the photodetector body layer,
wherein the carrier collection region comprises a region between the potential barrier maximum level and the carrier collection material layer, and
wherein the potential barrier maximum level comprises a height within the photodetector body layer that prevents photogenerated carriers created at a depth deeper than the potential barrier maximum level from transporting to the carrier collection region and the carrier collection material layer.

17. The method of claim 16, further comprising forming a bias semiconductor layer comprising a second doping type of material over the substrate.

18. The method of claim 17, further comprising depleting a doping concentration of any of the substrate, the photodetector body layer, and the bias semiconductor layer.

19. The method of claim 17, further comprising adjusting the height of the potential barrier maximum level.

20. The method of claim 17, further comprising configuring the substrate to prevent transporting of photogenerated carriers to the thin carrier collection region.
